(19) United States
(12) Patent Application Publication
(10) Pub. No.: US 2026/0128098 A1
(43) Pub. Date: May 7, 2026

(54) HIGH BANDWIDTH PARALLEL PROGRAM METHOD WITH DYNAMIC LATCH FOR THREE-DIMENSIONAL MEMORY ARRAY

(71) Applicant: Micron Technology, Inc., Boise, ID (US)

(72) Inventors: Tomoko Ogura Iwasaki, San Jose, CA (US); Tomoharu Tanaka, Kanagawa (JP); June Lee, Sunnyvale, CA (US); Yoshiaki Fukuzumi, Kanagawa (JP)

(73) Assignee: Micron Technology, Inc., Boise, ID (US)

(21) Appl. No.: 19/370,476

(22) Filed: Oct. 27, 2025

Related U.S. Application Data
(60) Provisional application No. 63/716,935, filed on Nov. 6, 2024.

(51) Int. Cl. G11C 16/08; G11C 16/10

(52) U.S. Cl. CPC G11C 16/08; G11C 16/10

(57) ABSTRACT

A three-dimensional memory device is provided. The device comprises an array of memory cells comprising a plurality of memory blocks having a first memory block. The first memory block includes a plurality of sets of sub-blocks. The device further comprises a global bit line; a controller; and a plurality of dynamic latch devices connected between the global bit line and the plurality of sets of sub-blocks. A first dynamic latch device of the plurality of dynamic latch devices is connected to a first set of sub-blocks. Different dynamic latch devices of the plurality of dynamic latch devices are connected to different sets of sub-blocks. The first dynamic latch device is controllable by the controller to store program data during a program operation in which the first set of sub-blocks connected to the first dynamic latch device are unselected sub-blocks during the program operation.

### RELATED APPLICATIONS

This application claims priority to U.S. Provisional Application No. 63/716,935 filed on November 6, 2024, titled “HIGH BANDWIDTH PARALLEL PROGRAM METHOD WITH DYNAMIC LATCH FOR THREE-DIMENSIONAL MEMORY ARRAY.” The contents of U.S. Provisional Application No. 63/716,935 are hereby incorporated by reference in their entirety for all purposes.

### TECHNICAL FIELD

This disclosure relates to one or more systems for memory, including techniques related to dynamic latch devices used for perform parallel read and program operations of a three-dimensional non-volatile memory array in a memory device.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIGS. 4A and 4B illustrate an example three-dimensional structure of a memory device in accordance with examples as disclosed herein.

FIG. 5 is a block diagram illustrating portions of a memory device with dynamic latch devices disposed above a three-dimensional memory array in accordance with examples as disclosed herein.

FIG. 6 is an example schematic of two dynamic latch devices each connected to a set of sub-blocks in a memory block for storing program data, in accordance with example as disclosed herein.

FIG. 7A is an example of two dynamic latch devices each connected to a set of sub-blocks in a memory block used for performing program operations in parallel to multiple sub-blocks, in accordance with example as disclosed herein.

FIG. 7B is a flowchart showing a method of programing a single sub-block using a dynamic latch device, in accordance with examples as disclosed herein.

FIG. 7C is a flowchart showing a method of programing multiple sub-blocks in parallel using the dynamic latch devices with a single programming pulse, in accordance with examples as disclosed herein.

FIG. 8A is an example of two dynamic latch devices each connected to a set of sub-blocks in a memory block used for performing read or program verify operations in parallel from multiple sub-blocks, in accordance with example as disclosed herein.

FIG. 8B is a flowchart showing a method of reading from a single sub-block using a dynamic latch device, in accordance with examples as disclosed herein.

FIG. 8C is a flowchart showing a method of reading multiple sub-blocks in parallel using multiple dynamic latch devices, in accordance with examples as disclosed herein.

FIG. 9 is an example waveform for showing applying a program pulse to cause the voltage of a floating pillar to change in accordance with examples as disclosed herein.

### DETAILED DESCRIPTION

Aspects of the present disclosure are directed to dynamic latch devices operated with a three-dimensional (3D) non-volatile memory array in a memory device for performing memory operations in parallel. A memory device can include one or more memory planes. For some types of non-volatile memory devices (e.g., NAND memory device), each memory plane includes of a set of physical memory blocks (or simply “blocks”). Each block includes a set of sub-blocks. Each sub-block includes a string of memory cells. A memory cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device includes memory cells arranged in a two-dimensional or a three-dimensional grid. Memory cells are formed onto a silicon wafer in an array of columns or strings and rows. Each column of memory cells corresponds to a sub-block of memory cells that are connected to a same bit line. Each row of memory cells is connected to a same word line. The intersection of a bit line and word line constitutes the address of the memory cell. A block hereinafter refers to a unit of the memory device used to store data and can include many sub-blocks (e.g., many strings of memory cells each connected to a bit line). The sub-blocks in a memory block are typically connected to a global bit line for performing read and program operations. The global bit line is connected to a page buffer. One or more blocks can be grouped together to form separate partitions (e.g., planes) of the memory device in order to allow concurrent operations to take place on each plane. An example memory device with blocks and sub-blocks are described in greater detail below.

During a program operation on a non-volatile memory device, certain phases can be encountered, including program and program verify. A program verify operation is similar to a read operation. For example, a high program voltage can be applied to a selected word line of a block of the memory device during a program phase, followed by a program verify phase where a verify voltage is applied to the selected word line. In existing technologies, a program operation is a single program operation, in which one sub-block is programmed in each operation with a programming pulse. In such a single program operation, a data pattern is read from a temporary storage location (e.g., a latch inside a page buffer) to determine whether the memory cell associated with a selected word line and located in the one sub-block is to be programmed or not, and a single programming pulse can be applied before the program verify phase occurs. This same process can then be repeated for each remaining sub-block to be programmed. This process, however, would require multiple programming pulses to be applied for programming multiple memory cells, resulting in a longer latency.

A dynamic latch device is provided to enable parallel program operations such as double program operations. For example, two sub-blocks may be programmed in one operation. In such a double program operation, dynamic latch devices may be used. In some examples, a dynamic latch device is used for one or more sub-blocks in a memory block and all dynamic latch devices in the memory block are connected to a local bit line. Accordingly, when a particular sub-block is selected for programming, all the dynamic latch devices need to be activated. This configuration may not be an efficient use of the dynamic latch devices and also may reduce the overall efficiency because it may still have longer latency due to multiple programming pulse needed, as described next in detail.

Using a double program operation as an example of a parallel program operation, two sub-blocks are programmed using two separate programming pulses, before the program verify phase occurs. Depending on the implementation, certain memory devices can utilize either a double verify operation or a seamless verify operation during the subsequent program verify phase. In either case, programming multiple sub-blocks involves causing multiple separate programming pulses to be applied to the selected word line. There are latencies associated with each programming pulse including ramping up and down the program voltage multiple times. These latencies increase the temporal length of the program operation, which can be especially impactful in high-priority and time-sensitive operations.

Thus, to reduce latency and improve overall operational efficiency, it is desired to have a memory device that can implement parallel program operations (e.g., double programming operations) using a single programming pulse. Based on the dynamic latch devices, a memory device can program memory cells in two or more separate sub-blocks using a single programming pulse applied to the selected word line. For example, as part of a programming operation, the controller of the memory device causes a pass voltage to be applied to each word line in a block of the memory device, including the word line connected to a selected sub-block having memory cells to be programmed and word lines connected to unselected sub-blocks. The pass voltage boosts a memory pillar channel voltage in each sub-block of the memory block to a higher boost voltage during this phase of the program operation. Once each pillar channel voltage is boosted, the controller can selectively discharge the pillars of one or more sub-blocks according to a data pattern of bits to be programmed to the selected sub-block during the program operation. Such a process can be repeated for two or more sub-blocks.

Once the pillar voltage boost is completed, the controller can cause a single programming pulse to be applied to the word lines of the selected sub-blocks. The pillars of the selected sub-blocks are discharged to the ground voltage and the memory cells in the selected sub-blocks are programmed. In the meantime, the pillars of the unselected sub-blocks remain at the boost voltage. These unselected sub-blocks are inhibited. In this manner, the memory device allows multiple sub-blocks to be programmed concurrently via the single programming pulse. Either a double verify operation or a seamless verify operation can then be performed during the subsequent program verify phase.

As the number of bits to be programmed per memory cell increases (e.g., for triple-level cell (TLC) or quad-level cell (QLC) memory for example, three or more bits are programmed in each memory cell), the number of latches used to store data associated with the program operation increases drastically. For example, to program a memory device configured as TLC memory, at least five latches may be needed for programming each sub-block (e.g., three latches to hold the three bits of data, one program inhibit latch, and one slow program latch). If multiple sub-blocks are to be programmed using a single program pulse, the number of required latches is also increased by a corresponding multiple. Many memory devices include the programming latches in a page buffer disposed under the memory array. A page buffer can take a significant amount of physical area in a physical layout of the memory device. In one example, the page buffer takes about 50% of the entire physical layout of the memory device. The page buffer is typically physically disposed below the array of memory cells and therefore, the space is limited. However, for performing program operations in parallel, more data may need to be stored in the page buffer. Thus, the limitation of the physical area of the page buffer also makes it difficult to add more latches in the page buffer. In turn, this makes it difficult to implement parallel program operations.

Aspects of the present disclosure address the above and other deficiencies by providing dynamic latch devices disposed above a 3D non-volatile memory array in a memory device. For example, one dynamic latch device can be connected to one or more sub-blocks in a memory block, referred to as a set of sub-blocks. Different dynamic latch devices are connected to different sets of sub-blocks in a memory block. In other words, there are essentially no local bit lines connecting a dynamic latch device to all sub-blocks in a memory block. This configuration enables the using of some of the dynamic latch devices as storage device to store program data during parallel program operations. These dynamic latch devices used to store program data are connected to unselected sub-blocks during a particular program operation. As described above, the page buffer occupies a large physical layout area and thus only a fixed number of latches can be implemented in the page buffer under the memory array of the memory device. The dynamic latch devices described in the present disclosure are disposed above the memory array and can be used to hold program data for programming multiple selected sub-blocks in parallel. In this manner, the dynamic latch devices are used effectively to supplement the shortage of the storage devices in the page buffer and in turn enable the parallel programming operations with a single programming pulse. This circuit configuration of the dynamic latch devices, therefore, reduces the latency of programming operations by more effectively using the dynamic latch devices.

In some examples, the latches in the page buffer and the dynamic latch devices placed above the memory array can be used together for enabling efficient parallel programming operations. The latches in the page buffer can include a sense amplifier latch, as well as one set (e.g., a pair) of even cache register latches and one set (e.g., a pair) of odd cache register latches, which enable each page buffer circuit to be used with multiple sub-blocks of the array. The other latches used to program multiple sub-blocks with a single programming pulse (e.g., those latches used to store the data patterns to be programmed to the multiple sub-blocks) can be those dynamic latch devices disposed above the memory array. The latches above the array can be coupled to the latches in the page buffer disposed under the array such that data can be routed therebetween. In general, the open area above the memory array is not space constrained and multiple layers (e.g., CMOS layers) can be formed to contain the associated latches.

Advantages of this approach include, but are not limited to, improved performance in the memory device. The dynamic latch devices disposed above the memory array can be used as extra storage devices for holding program data in parallel program operations, if they are connected to unselected sub-blocks. The arrangement of the dynamic latch devices above the memory array provides the number of dynamic latch devices used to program multiple sub-blocks in the memory block concurrently (e.g., simultaneously) using a single programming pulse, without increasing the footprint of the memory device. This results in the ability for fewer program operations to be performed (e.g., one half the number of program operations) for the same amount of data being programmed to the memory device, without materially increasing the size and/or area occupied by the memory device. Accordingly, the increased parallelism afforded by the dynamic latch device configuration described herein reduces the latency associated with the entire programming operation, and improves the overall operational efficiency and programming performance.

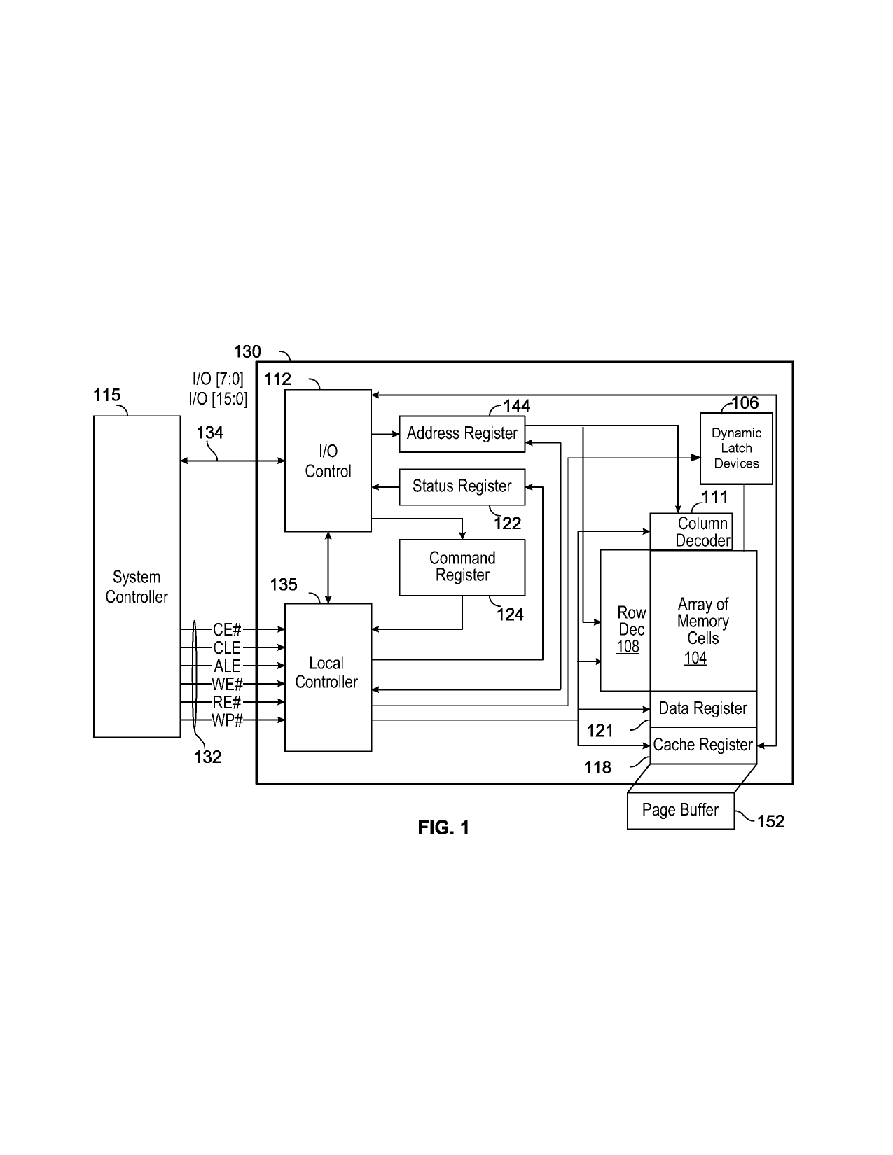

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

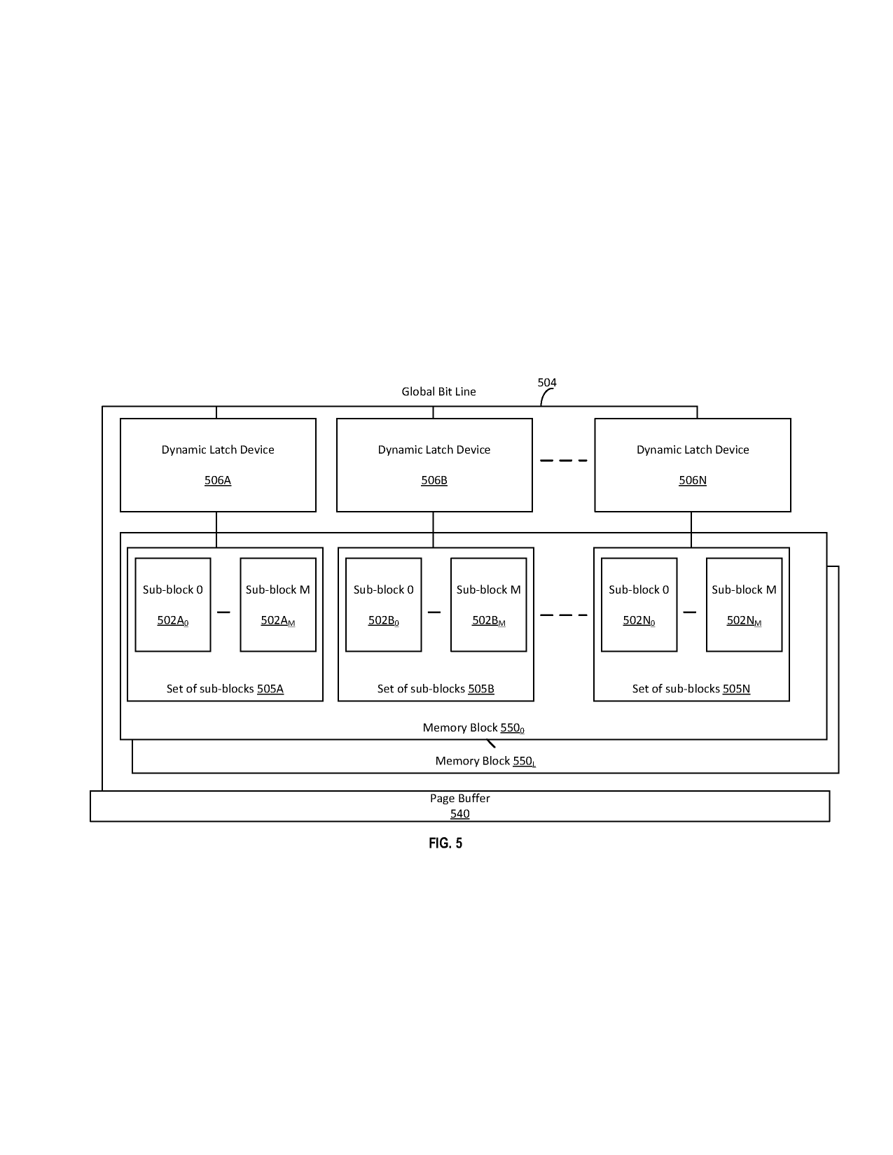

FIG. 1 also illustrates that dynamic latch devices 106 can be disposed above the array of memory cells 104, where the page buffer 152 is normally disposed below the array 104. Dynamic latch devices 106 are connected to the sub-blocks of memory blocks in the array of memory cells 104. Dynamic latch devices 106 are also connected to a global bit line (shown in FIG. 5). As described in more detail below, during parallel program operations in which multiple sub-blocks are programmed in parallel, some of the dynamic latch devices 106 can be configured as extra storage devices to store program data. In some examples, dynamic latch devices 106 are also connected to page buffer 152. As a result, latches in the page buffer 152 and dynamic latch devices 106 can both be used in program operations to program multiple sub-blocks in parallel. Dynamic latch devices 106 are controlled by controller 135 (and/or controller 115) and are described in greater detail below.

As shown in FIG. 1, memory device 130 receives various control signals via local controller 135 from system controller 115 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

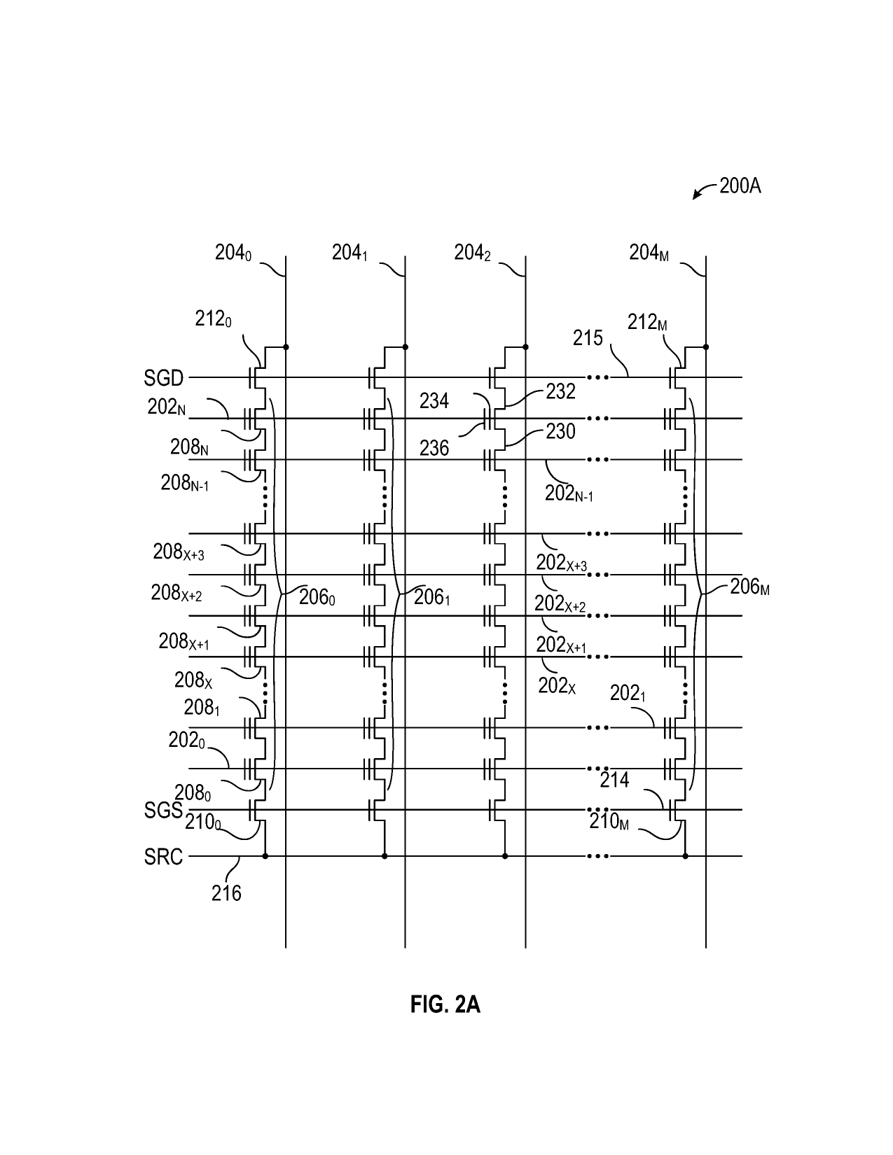

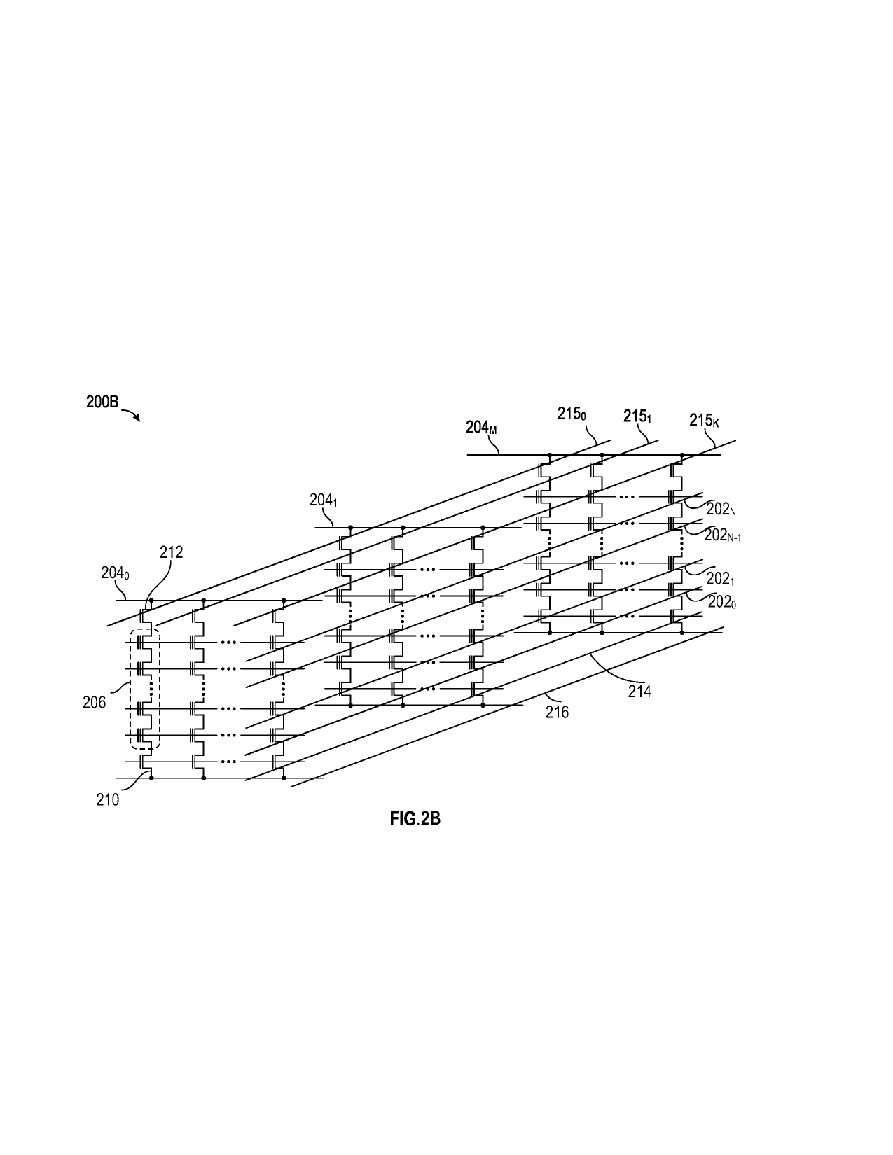

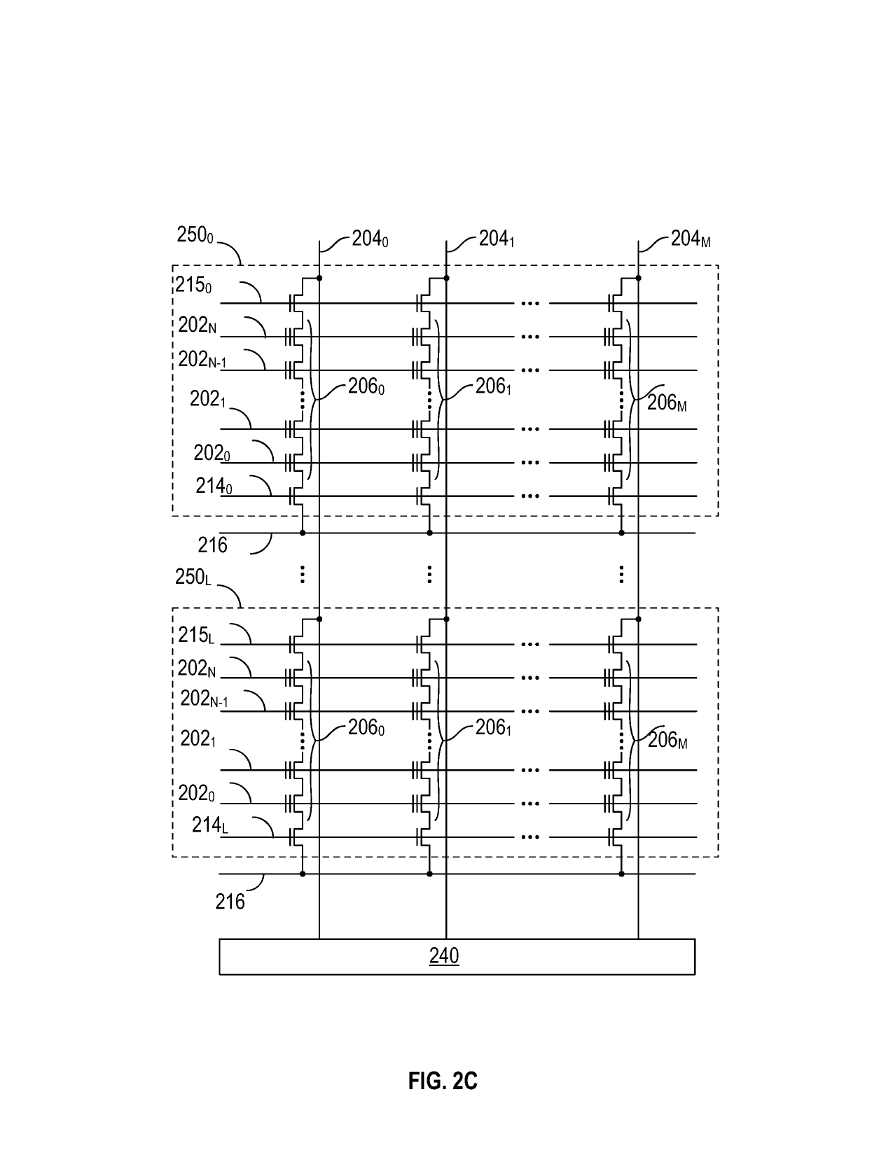

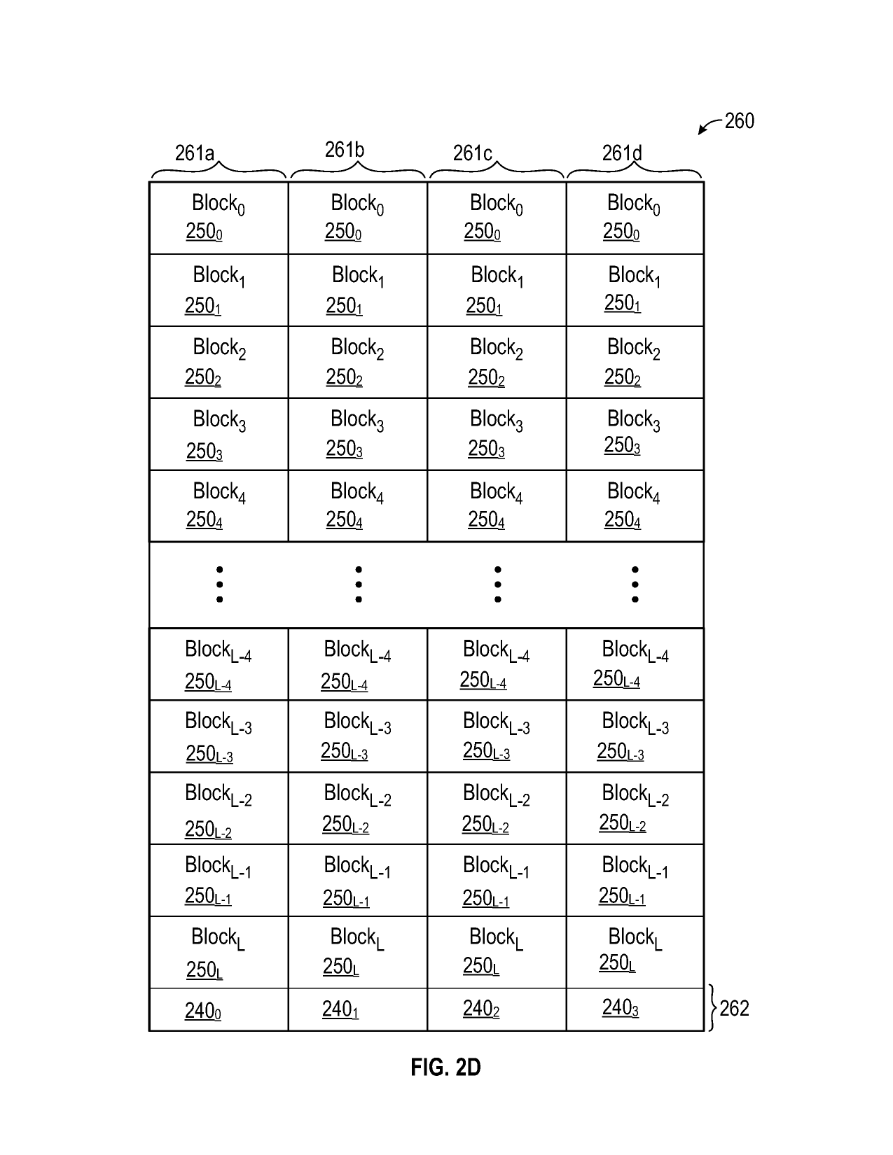

FIG. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

FIG. 2D is a block schematic of a portion of an example array of memory cells 260. Array of memory cells 260 can be used as array 104 in a memory device 130. The array of memory cells 260 is depicted as having four memory planes 261 (e.g., memory planes 261a-261d). Each of the memory planes 261 may refer to a group of memory blocks of memory cells 250. Each memory plane 261 can be in communication with a respective buffer portion 240, which can collectively form a page buffer 262. Page buffer 262 may be used to implement page buffer 152 shown in FIG. 1. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

In some cases, concurrent operations may be performed on different planes. For example, concurrent operations may be performed on memory cells within different blocks 250 so long as the different blocks 250 are in different planes 261. In some cases, an individual memory block 250 may be referred to as a physical block, and a virtual block may refer to a group of blocks 250 within which concurrent operations may occur. For example, concurrent operations may be performed on four blocks of 250₀ that are within planes 261a, 261b, 261c, and 261d, respectively, and the four blocks of 250₀ may be collectively referred to as a virtual block. In some cases, a virtual block may include blocks from different memory devices. In some cases, the physical blocks within a virtual block may have the same block address within their respective planes. In some cases, performing concurrent operations in different planes 261 may be subject to one or more restrictions, such as concurrent operations being performed on memory cells within different pages that have the same page address within their respective planes 261 (e.g., related to command decoding, page address decoding circuitry, or other circuitry being shared across planes 261).

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

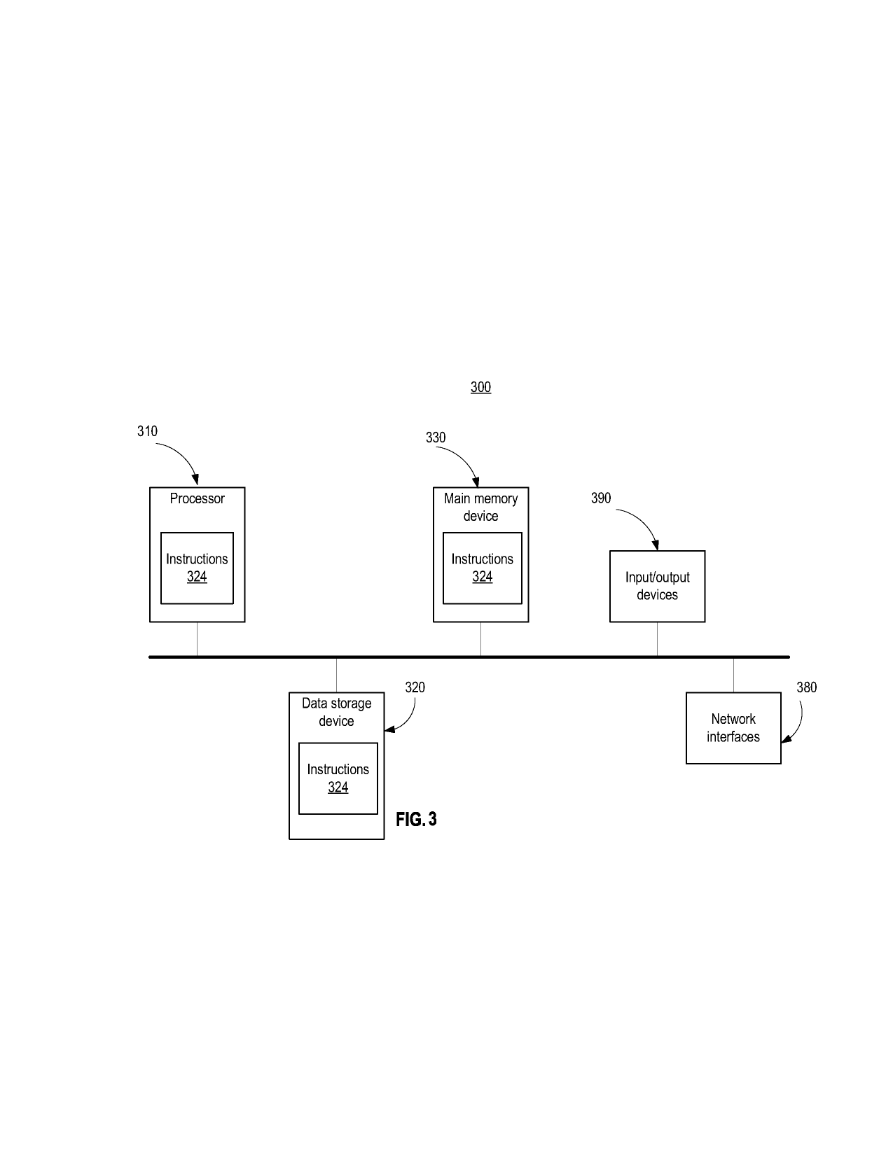

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-9, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-9 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-9. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

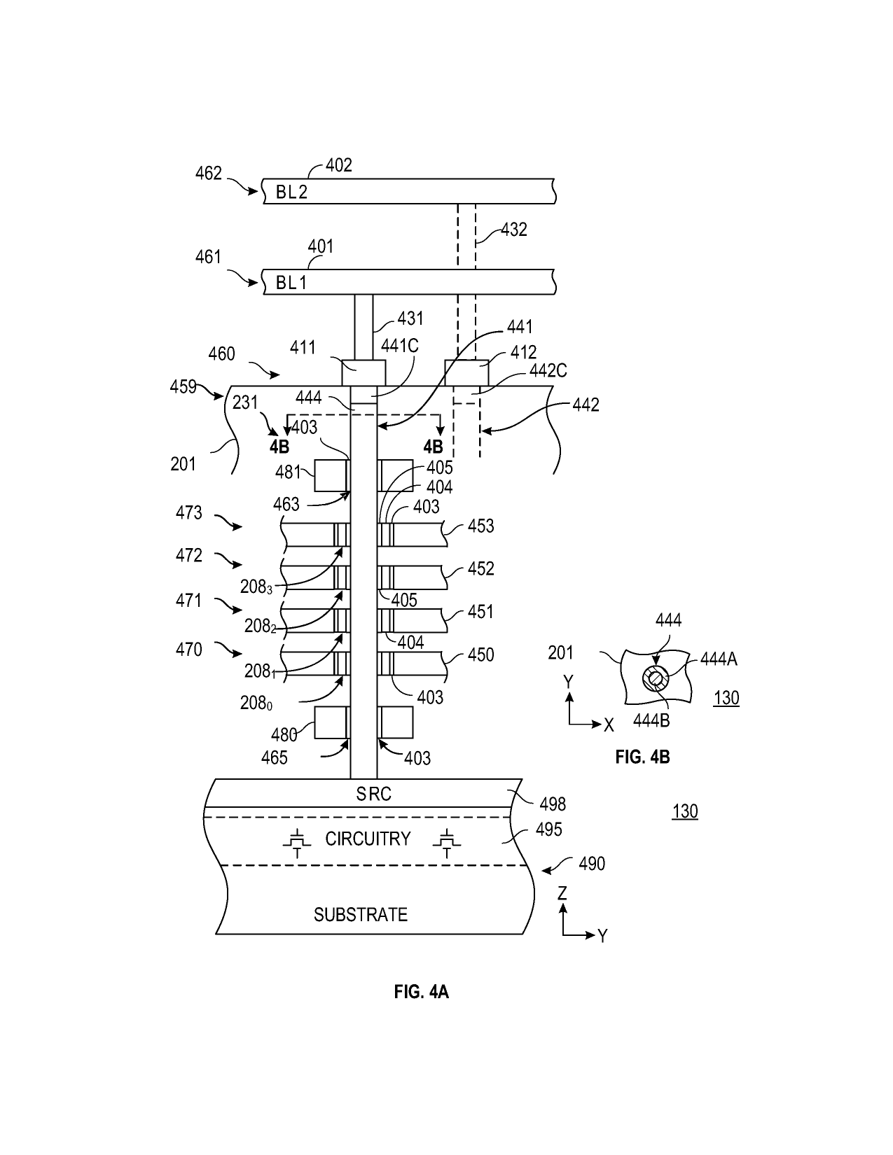

FIG. 4A- FIG. 4B shows a side view (e.g., a cross section with respect to the X-Z directions) of a portion of the three-dimensional structure of memory device 130 including a structure of memory cell string 231 (e.g., a NAND string) having a pillar 441, according to some embodiments described herein. FIG. 4A shows the structure of one memory cell string (e.g., memory cell string 231) of memory device 130. However, other memory cell strings (e.g., NAND strings 206₀ – 206_{M} in FIG. 2A and NAND strings 206 in FIG. 2B) can have a similar or the same structure as memory cell string 231 shown in FIG. 4A.

Starting from the top of FIG. 4A, memory device 130 have data lines 401 and 402 (e.g., corresponding to bit lines 204 in FIGS. 2A, 2B, and 2C) coupled to conductive structures 431 and 432, respectively, and coupled to conductive contacts 411 and 412, respectively. Data lines 401 and 402 are therefore electrically connected to pillars 441 and 442, respectively, via the conductive contacts 411 and 412, respectively. It is understood that memory device 130 can include many other similar data lines, conductive structures, and conductive contacts, which are not shown for simplicity.

FIGS. 4A-4B shows directions X, Y, and Z that can be relative to the physical directions (e.g., dimensions) of the structure of memory device 130. For example, the Z-direction can be a direction perpendicular to (e.g., vertical direction relative to) a substrate (e.g., a semiconductor substrate) of memory device 130. The Z-direction is perpendicular to the X-direction and Y-direction (e.g., the Z-direction is perpendicular to an X-Y plane of memory device 130).

As shown in FIG. 4A, data lines 401 and 402 can carry signals (e.g., bit line signals) BL1 and BL2, respectively. In the physical structure of memory device 130, data lines 401 and 402 can be structured as conductive lines and have respective lengths extending in the Y-direction. The data lines (e.g., data lines 401 and 402) of memory device 130 can be formed on different levels (e.g., layers) in the physical structure of memory device 130. For example, data lines 401 can be formed on one level (e.g., a lower level 461) of memory device 130, and data lines 402 can be formed on another level (e.g., an upper level 462) of memory device 130. Although not shown in FIG. 4A, multiple data lines can be located side-by-side in any particular level. For example, level 461 may have multiple data lines and level 462 may also have multiple data lines. Data lines in the same level can be separated from each other by a distance (e.g., a gap) in the X-direction. The gaps between data lines in the same level may be the same or different. As shown in FIG. 4A, each of data lines 401 and 402 can have a thickness in the Z-direction and a width in the X-direction. Each of the thickness (in the Z-direction) and the width (in the X-direction) is less than the length (in the Y-direction). The thickness can be less than, equal to, or greater than the width.

In FIG. 4A, each of conductive structures 431 and 432 can have a length extending in the Z-direction. In some examples, the length of conductive structure 431 can be less than the length of conductive structure 432, because level 461 is a lower level that is located closer to memory array 201. Each of conductive structures 431-432 can include (e.g., can be formed from) a conductive material that extends in the Z-direction. Examples of the conductive material include metal, alloy, conductively doped polysilicon, or other conductive materials. Although not shown in FIG. 4A, memory device 130 can include a dielectric material (e.g., silicon dioxide) formed between levels 462 and 461. The dielectric material can be formed before conductive structures 431 and 432. Then, openings (e.g., holes (e.g., vertical vias)) can be formed in the dielectric material. The material of each of conductive structures 431-432 can be formed (e.g., deposited) inside a respective opening of the openings.

As shown in FIG. 4A, each of conductive structures 431 and 432 can be coupled to (e.g., in electrical contact with) a respective conductive contact among conductive contacts 411 and 412 and coupled to (e.g., in electrical contact with) a respective data line among data lines 401 and 402. For example, conductive structure 431 can include an end (e.g., bottom end) coupled to (e.g., directly contacting) conductive contact 411, and another end (e.g., top end) coupled to (e.g., directly contacting) data line 401. In another example, conductive structure 432 can include an end (e.g., bottom end) coupled to (e.g., directly contacting) conductive contact 412, and another end (e.g., top end) coupled to (e.g., directly contacting) data line 402.

As shown in FIG. 4A, memory cell string 231 can include pillars (e.g., vertical pillars) 441 and 442. Pillars 441 and 442 can include pillar contacts 441C and 442C, respectively, located on the same level (e.g., level 459) of memory device 130. Pillars 441 and 442 can be located under (e.g., directly under) respective conductive contacts 411 and 412, which are under (e.g., directly under) respective conductive structures 431 and 432. Conductive structures 431 and 432 can be coupled to (e.g., in electrical contact with) pillars 441 and 442, respectively, through conductive contacts 411 and 412, respectively. Thus, as shown in FIG. 4A, data lines 401 and 402 can be coupled to (e.g., electrically coupled to) pillars 441 and 442, respectively, through respective conductive structures 431 and 432 and respective conductive contacts 411 and 412.

As described above, data lines 401 and 402 are located in levels 461 and 462, respectively. Levels 461 and 462 are in portion of memory device 130 that is located above memory array 201 in the Z-direction. Memory array 201 is located above a substrate 490 of memory device 130 in the Z-direction. As described above, a memory array such as memory array 201 comprises multiple memory cell strings (one of which is shown as memory cell string 231).

As shown in FIG. 4A, pillar (e.g., a vertical pillar) 441 can be a part of memory cell string 231 and can have a length extending in the Z-direction (e.g., extend vertically with respect to substrate 490). Pillar 441 can extend through memory cells 208₀, 208₁, 208₂, and 208₃ of memory cell string 231. Pillar 441 can include (e.g., can be formed from) a conductive material (e.g., conductively doped polysilicon). Each of memory cells 208₀, 208₁, 208₂, and 208₃ can include a structure of transistor (e.g., a memory cell transistor). Part of pillar 441 can form the channel region (e.g., to conduct current) of the transistor of each memory cells 208₀, 208₁, 208₂, and 208₃. It is understood that while FIG. 4A only shows four memory cells 208₀-208₃ , memory cell string 231 can include any number of memory cells that share a same pillar (e.g., pillar 441).

As described above, pillar contact 441C can be formed from conductively doped polysilicon, metal, or other conductive materials. Pillar 441 can include a portion 444. Pillar contact 441C and portion 444 of pillar 441 can include the same conductive material or different conductive materials. Conductive structure 431, conductive contact 411, and pillar 441 can be part of a circuit path (e.g., a conductive channel of memory cell string 231) between data line 401 and a conductive region 498 (associated with an SRC line). Conductive region 498 can be a part of a common source line (e.g., common source line or source plate 216 in FIG. 2A). Conductive structure 431 and pillar 441 can have the same material or different materials. In FIG. 4A, during a memory operation (e.g., read or write operation) of memory device 130, a circuit path (e.g., a current path) can be formed between data line 401 and conductive region 498 through conductive structure 431, conductive contact 411, and pillar 441 (which includes pillar contact 441C and portion 444 of pillar 441).

Substrate 490 of memory device 130 can include a semiconductor substrate (e.g., silicon-based substrate). For example, substrate 490 can include a p-type silicon substrate or an n-type silicon substrate. As shown in FIG. 4A, memory cells 208₀, 208₁, 208₂, and 208₃of memory cell string 231 can be located along (e.g., adjacent) respective portions of pillar 441 in different levels (in the Z-direction) of memory device 130. For example, memory cells 208₀, 208₁, 208₂, and 208₃ can be located one over another (e.g., formed vertically) in levels 470, 471, 472, and 473, respectively, of memory device 130. Memory cells of other memory cell strings of memory device 130 can also be located on respective levels 470, 471, 472, and 473.

By stacking the memory cells in different levels, the memory device forms a 3D structure that has a higher capacity than a 2D device. In a typical 3D memory device (e.g., device 130 shown in FIG. 4A), for example, multiple levels (e.g., levels 470, 471, 472, and 473) are stacked together with one or more memory pillars (e.g., pillars 441 and 442) disposed vertically in the middle. The memory pillars may act as the channel region of the memory device. The multiple levels (e.g., layers or tiers) of the memory device may form groups or decks. A deck of a 3D memory device may be processed together (e.g., patterned and/or etched together) when forming the memory pillar associated thereof. A level of the memory device may have one or more access lines (e.g., word lines) or access line groups (e.g., word line groups). Each deck may have one or more access line segments (e.g., word line segments). An access line segment may have fewer or more access lines than those in a deck. For example, a deck may have two word line segments distributed in one or more levels. In some cases, certain memory operations (e.g., an erase operation) can be performed to a word line group (e.g., a deck), and not to the entire memory block. By not performing an operation to the entire memory block, the particular operation may be performed faster.

FIG. 4A further illustrates that access lines 450, 451, 452, and 453 of memory device 130 can be located along (e.g., adjacent) respective portions (in the Z-direction) of pillar 441 in the same levels (e.g., levels 470, 471, 472, and 473, respectively) that memory cells 208₀, 208₁, 208₂, and 208₃ are located. Access lines can include, for examples, word lines or control gates. Access lines 450, 451, 452, and 453 can include (e.g., can be formed from) a conductive material (or materials). Example materials for access lines 450, 451, 452, and 453 include metal, alloy, doped polysilicon, other conductive materials.

In FIG. 4A, a select line (e.g., drain select gate or SGD) 481 can have a length extending in the X-direction (e.g., perpendicular to the lengths (in the Y-direction) of data lines 401 and 402). The materials of select line 481 can include a conductive material (e.g., conductively doped polysilicon, metal, other conductive material). FIG. 4A shows an example where another select line (e.g., source select gate or SGS) 480 can have a structure (e.g., shape, material, or both) similar to (or the same as) that of select line 481. In some examples, select line 480 can have a structure (e.g., shape, material, or both) similar to (or the same as) that of each of access lines 450, 451, 452, and 453.

As shown in FIG. 4A, a transistor (e.g., source select transistor) 465 and a transistor (e.g., drain select transistor) 463 can be located along (e.g., adjacent) respective portions of pillar 441 in the Z-direction. Memory cells 208₀, 208₁, 208₂, and 208₃ of memory cell string 231 can be located along the portion of pillar 441 that is between transistors 465 and 463.

Memory cell string 231 can include materials 403, 404, and 405 formed between portion 444 of pillar 441 and a respective access line among access lines 450, 451, 452, and 453. Material 403 can also be formed between pillar 441 and each of select lines 480 and 481. Materials 403, 404, and 405 located at a particular memory cell (among memory cells 208₀, 208₁, 208₂, and 208₃) can be a part (e.g., a memory element) of that particular memory

cell. As shown in FIG. 4A, the combination of materials 403, 404, and 405 of a memory cell (among memory cells 208₀, 208₁, 208₂, and 208₃) can be separated from (in the Z-direction) the combination of materials 403, 404, and 405 of another memory cell (among memory cells 208₀, 208₁, 208₂, and 208₃).

Material 403 can include a charge blocking material (or charge blocking materials), for example, a dielectric material (e.g., silicon nitride) that is capable of blocking a tunneling of a charge. Material 404 can include a charge storage material (or charge storage materials) that can provide a charge storage function to represent a value of information stored in memory cells 208₀, 208₁, 208₂, and 208₃. For example, material 404 can include polysilicon (e.g., conductively doped polysilicon), which can be either a p-type polysilicon or an n-type polysilicon. The polysilicon can be configured to operate as a floating gate (e.g., to store charge) in a memory cell (e.g., a memory cell 208₀, 208₁, 208₂, and 208₃). In another example, material 404 can include a dielectric material (e.g., silicon-nitride based material or other dielectric materials) that can trap charge in a memory cell (e.g., a memory cell 208₀, 208₁, 208₂, and 208₃). Material 405 can include a tunnel dielectric material (or tunnel dielectric materials), for example, silicon dioxide, that is capable of allowing tunneling of a charge (e.g., electrons).

As shown in FIG. 4A, memory device 130 can include circuitry 495 located (e.g., formed) under memory array 201 (e.g., located directly under memory cell string 231). Circuitry 495 can include circuit elements (e.g., transistors T) coupled to other circuit elements (e.g., coupled to data lines 401-402) of memory device 130. The circuit elements (e.g., transistors T) of circuitry 495 can be configured to perform part of a function of a memory device (e.g., memory device 130). For example, circuitry 495 can include decoder circuits, driver circuits, buffers (e.g., page buffers), sense amplifiers, charge pumps, and other circuitry of memory device 130. In an alternative structure of memory device 130, circuitry 495 can be located (e.g., formed) above memory array 201 (instead of under memory array 201). For example, in the alternative structure of memory device 130, circuitry 495 can be located above memory array 201 and under data lines 401 and 402, or located between data lines 401 and 402 of memory array 201 in the Z-direction. In another example, in the alternative structure of memory device 130, circuitry 495 can be located above memory array 201 and above data lines 401 and 402 in the Z-direction.

A different view of pillar 441 along a cross-sectional line 4B-4B is shown in FIG. 4B. FIG. 4B shows a top view (e.g., a cross section with respect to the X-Y plan) of portion 444 of pillar 441 along line 4B-4B of FIG. 4A. As shown in FIG. 4B, portion 444 of pillar 441 can include material 444A and material 444B surrounded by material 444A. Material 444A can be (or can include) a part of a conductive structure (e.g., a conductive channel) of pillar 441. Material 444B can include a dielectric material. In an alternative structure of pillar 441, material 444B can be omitted from pillar 441, such that the entire portion 444 of pillar 441 can include material 444A (without material 444B).

FIG. 5 is a block diagram illustrating portions of a memory device (e.g., memory device 130) with dynamic latch devices disposed above a three-dimensional non-volatile memory array in accordance with some embodiments of the present disclosure. As illustrated, the memory device includes an array of memory cells (e.g., array 104 in FIG. 1) having multiple memory blocks 550₀-550_{L} (collectively as 550). The multiple memory blocks 550 can be included in multiple planes of the array of memory cells. The memory device shown in FIG. 5 also includes a page buffer 540, which can be the same or similar to page buffer 152 or 240 shown in FIGS. 1 or 2C, respectively. In one embodiment, page buffer 540 is physically disposed under the memory array including the memory blocks 550. In one embodiment, page buffer 540 includes a fixed number of latches or other data storage elements, such as data register 121 and cache register 118, described above.

As shown in FIG. 5, in one embodiment, a plurality of dynamic latch devices 506A-506N are physically disposed above the memory array including memory blocks 550 (e.g., physically located on an opposite side of the memory blocks 550 from page buffer 540). As described above, below the memory blocks 550, the physical area is space-limited and therefore it is difficult to place more latch devices other than those latches in the page buffer 540. Dynamic latch devices 506 in FIG. 5 correspond to dynamic latch devices 106 in FIG. 1.

In some examples, dynamic latch devices 506 include additional latches used to program, in parallel, multiple sub-blocks (e.g., one of sub-block 0 — sub-block M in each set of sub-blocks 505A-505N) of memory blocks 550 with a single programming pulse. The additional latches include storage devices used to store the data patterns to be programmed to multiple selected sub-blocks. The dynamic latch devices that are used to store program data are connected to unselected sub-blocks during any particular program operations. As illustrated in the example shown in FIG. 5, a memory plane of the memory device may include multiple memory blocks 550₀-550_{L}. Each memory block 550 may include multiple sets of sub-blocks. For example, memory block 550₀ includes sets of sub-blocks 505A-505N (collectively as 505). In each set of sub-blocks 505, there are multiple sub-blocks containing strings of memory cells. For example, the set of sub-blocks 505A includes sub-block 0 – sub-block M (illustrated as sub-blocks 502A₀-502A_{M}). Similarly, the set of sub-blocks 505B includes its corresponding sub-block 0- sub-block M (illustrated as sub-blocks 502B₀-502B_{M}), and so on. A set of sub-blocks may include, for example, 1, 2, 4, etc. sub-blocks. Each sub-block in a set of sub-blocks includes, for instance, a string of memory cells (e.g., a NAND string 206 shown in FIGS. 2A and 2B). Therefore, each sub-block includes serially-connected memory cells. Each sub-block may also include select transistors like SGD 212 and SGS 210 shown in FIGS. 2A and 2B.

In the configuration shown in FIG. 5, one or more sub-blocks in a set of sub-blocks are connected to the same dynamic latch device. As shown in FIG. 5, the sub-blocks 502A₀-502A_{M} in the set of sub-blocks 505A are all connected to dynamic latch device 506A; the sub-blocks 502B₀-502B_{M} in the set of sub-blocks 505B are all connected to dynamic latch device 506B; and so forth. If a dynamic latch device 506 is used to store program data, it is connected to unselected sub-blocks in a set of sub-blocks. The unselected sub-blocks are inhibited during program operations (e.g., the memory cells in the unselected sub-blocks have already been programmed). Therefore, the dynamic latch device storing program data are sometimes referred to as inhibit latches. As described below in more detail, during parallel program operations, multiple selected sub-blocks are programmed in parallel. In some embodiments, in each set of multiple sets of sub-blocks, one sub-block is programmed and thus multiple sub-blocks in different sets of sub-blocks can be programmed in parallel (e.g., simultaneously). During program operations, dynamic latch devices that store program data (e.g., a data pattern) can transfer the stored data to the selected sub-blocks in the multiple sets of sub-blocks for programming the selected sub-blocks in parallel. The storing of the program data in dynamic latch devices connected to unselected sub-blocks and the programming processes are described in greater detail below.

In some embodiments, the dynamic latch device described in the present disclosure can not only be used as a storage device to store program data, but also be configured to perform sense amplification during a read operation. Such a dynamic latch device may also be referred to as a sense latch. The sense amplification capability of the dynamic latch device can improve the sensing capability of the 3D memory device as the pillar current becomes smaller due to the long distance of the pillar. In particular, a string of memory cells in a sub-block may have many memory cells fabricated in a 3D structure. The pillar of these memory cells (e.g., the channel region) becomes longer and longer as the number of memory cells increases. As a result, the pillar current becomes smaller and smaller because the resistance of the pillar increases. During a read operation, the pillar current is sensed usually using sense amplifiers in the page buffer. However, if the pillar current is small (e.g., in the pico amp range), the sensing using the sense amplifiers in the page buffer can become difficult and time consuming. The dynamic latch device described herein, during a read operation, can perform sense amplification and thus provide amplified current for sensing by the sense amplifier in the page buffer. As a result, the sensing capability can be improved by using the dynamic latch devices.

As described above, page buffer 540 may include latches for storing program data (e.g., three latches for storing three bits of program data for programming a TLC cell). In one example, page buffer 540 is also connected with the dynamic latch devices 506 such that they can be used together or in any desired manner to enable efficient parallel program operations of multiple sub-blocks. It is understood that FIG. 5 is simplified and therefore it does not illustrate other additional latches, e.g., those storing temporary information that can be used to accelerate the program operation and reduce the program time (e.g., the state information of a memory cell(s) on an adjacent word line, SSPC (selective slow program convergence) data for a different sub-block(s)), etc.

With continued reference to FIG. 5, in one embodiment, the multiple dynamic latch devices 506A-506N are all connected to a global bit line 504. Global bit line 504 is connected to the page buffer 540, such that the bit line current can be sensed by the sense amplifiers in page buffer 540. Unlike existing structures, the circuit configuration shown in FIG. 5 does not have local bit lines connecting multiple dynamic latch devices and sub-blocks. For instance, in an existing structure, each dynamic latch may be connected to all the subblocks of the multiple sets of sub-blocks in a memory block via a local bit line. As a result, when a certain sub-block is selected for performing an operation, all the dynamic latches connected to the memory block are activated. Therefore, it would be difficult to effectively use any of latches connected to the unselected sub-blocks to store program data, because there are no inhibit latches for the memory block.

As shown in FIG. 5, unlike the existing structures, the circuit configuration shown in FIG. 5 has no local bit line connecting all sub-blocks in a memory block. Each dynamic latch device 506 is only connected to the respective set of sub-blocks 505 and no other sets of sub-blocks in the same memory block 550. For example, dynamic latch device 506A is connected only to the set of sub-blocks 505A, and no other sets of sub-blocks. Dynamic latch device 506B is connected only the set of sub-blocks 505B, and no other sets of sub-blocks. Other dynamic latch devices 506 are connected in a similar way. Thus, while the plurality of dynamic latch devices 506 are connected between the global bit line 504 and the plurality of sets of sub-blocks 505, any particular dynamic latch device (e.g., device 506A, 506B, etc.) of the plurality of dynamic latch devices 506 is only connected to a corresponding set of sub-blocks (e.g., set 505A, 505B, etc.) of the plurality of sets of sub-blocks 505, and no other sets of sub-blocks. In other words, different dynamic latch devices 506 are connected to different sets of sub-blocks 505. In this manner, as described in greater detail below, any dynamic latch device is activated only when a sub-block in a corresponding set of sub-blocks is selected for performing operations (e.g., read/program/program verify). Other dynamic latch devices are not activated if the corresponding sets of sub-blocks are unselected. Some of these dynamic latch devices can therefore be used to store program data. This circuit configuration enables the parallel program operations that can program multiple sub-blocks simultaneously, thereby improving overall operational efficiency.

In one embodiment, as shown in FIG. 5, a dynamic latch device 506 is connected to multiple sub-blocks (e.g., 2, 4, 6, etc. sub-blocks) in a set of sub-blocks. As described herein, some of these dynamic latch devices can hold data to be programmed to multiple sub-blocks in parallel, by using a single programming pulse. For example, using a single program pulse, dynamic latch devices 506A and 506B can be activated to program sub-block 502A₀ in set 505A and sub-block 502B₀ in set 505B, while other dynamic latch devices (e.g., 506N) are inactivated and are used to store and provide program data for programming sub-blocks 502A₀ and 502B₀. In particular, a controller (e.g., controller 135) can be configured to, during a program operation, obtain the program data from the dynamic latch device 506N, which stores the program data instead of, or in addition to, from the page buffer 540. The controller can perform the program operation of one or more sub-blocks 502 (e.g., 502A₀ and 502B₀) that are not connected to the dynamic latch device 506_{N}. The one or more sub-blocks are selected sub-blocks in the plurality of sets of sub-blocks for performing the program operation. The selected memory cells in the selected sub-blocks 502 (e.g., 502A₀ and 502B₀) are thus programmed with a single programming pulse with the data stored in the dynamic latch device 506N. Typically, for programming multiple-level memory cells (e.g., TLC, QLC), multiple programming pulses are applied in a sequence with increasing voltage levels. Using the dynamic latch devices 506 discloses herein, for each programming pulse in the sequence, a selected memory cell in each of the selected sub-blocks 502 (e.g., 502A₀ and 502B₀) can be programmed in parallel. In some examples, multiple programming pulses are needed if a program has not been completed. On the other hand, if the first programming pulse is sufficient to complete the program of the memory cells, subsequent programming pulses may not be needed.

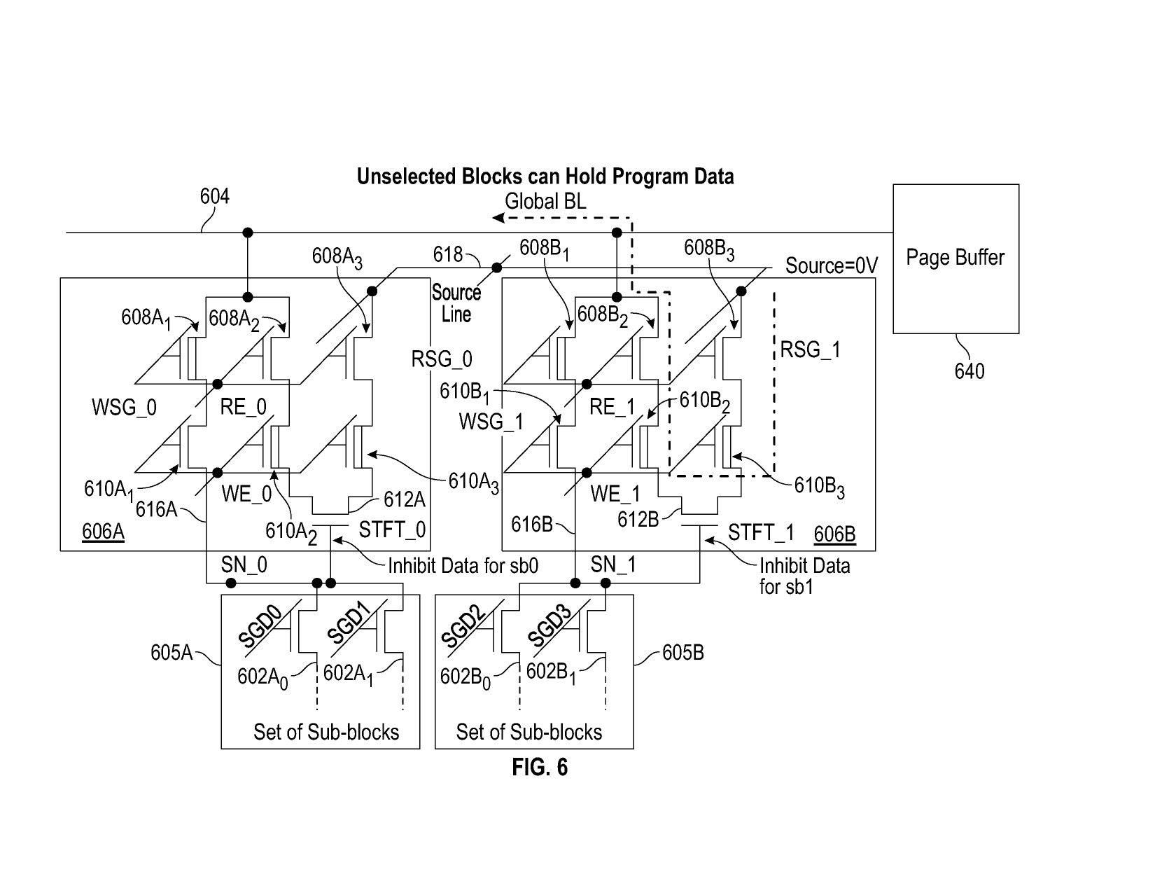

An example circuit for dynamic latch devices is illustrated in FIG. 6. FIG. 6 shows two dynamic latch devices 606A and 606B, which can be used to implement dynamic latch device 506 in FIG. 5 or device 106 in FIG. 1. Dynamic latch device 606A is described in detail below, with the understanding that similar descriptions can be used for dynamic latch device 606B because it has the same configuration as device 606A. As shown in FIG. 6, dynamic latch device 606A has a write transistor group (denoted as WSG_0), a read transistor group (denoted as RSG_0), and a storage device 612A (denoted as STFT_0). The storage device 612A can be a transistor, a capacitor, or any other circuit element that can store electrical charges.

In one embodiment, the write transistor group (denoted as WSG_0) comprises a plurality of write transistors 608A₁, 608A₂, 610A₁, and 610A₂. The read transistor group (denoted as RSG_0) includes a plurality of read transistors 608A₃ and 610A₃. As shown in FIG. 6, in one example, the write transistors 608A₁ and 610A₁are connected in series; and the write transistors 608A₂ and 610A₂ are connected in series. Both write transistors 608A₁ and 608A₂ are connected to the global bit line 604 (e.g., at their drain or source electrodes). The write transistor 610A₁ is directly connected to the set of sub-blocks 605A (e.g., by its source or drain electrode) and the connection node is referred as the sense memory node (denoted as SN_0). The read transistor 608A₃and 610A₃ are connected in series (e.g., at their drain or source electrodes). The read transistor 608A₃ is connected to the source line 618 (e.g., at its drain or source electrode). The storage device 612A is connected between the write transistor group and the read transistor group, and particularly, because write transistor 610A₂ and the read transistor 610A₃. For instance, the drain electrode of device 612A may be connected to the write transistor 610A₂ and the source electrode may be connected to the read transistor 610A₃, or vice versa. The gate electrodes of the transistors 608A₁, 608A₂, and 608A₃ are controlled by control signal RE_0; and the gate electrodes of the transistors 610A₁, 610A₂, and 610A₃ are controlled by control signal WE_0. In some examples, RE_0 and WE_0 each includes multiple bits of control signals for controlling the transistors individually or collectively.

As shown in FIG. 6, the set of sub-blocks 605A includes two sub-blocks 602A₀ and 602A₁, and only a portion of the sub-blocks are shown. Each of sub-blocks 602A₀ and 602A₁ includes a string of memory cells (e.g., a string 206 shown in FIGS. 2A and 2B). Each string of memory cells in a sub-block 602 is connected to a select gate drain (e.g., SGD0 or SGD1) transistor. While FIG. 6 only shows that the set of sub-blocks 605A includes two sub-blocks, it can include more sub-blocks.

Continuing with FIG. 6, the write transistor 610A₁ (e.g., at its source electrode), the storage device 612A (e.g., at its gate electrode), and the SGD0 and SGD1 transistors (e.g., at their drain electrode) of the sub-blocks 602A₀ and 602A₁ respectively, are all connected together to the sense memory node SN_0. In this example, the storage device 612A can be a transistor, which has its source and drain electrodes connected to write transistor 610A₂ and read transistor 610A₃, respectively (or vice versa). Program data can be stored on this sense memory node SN_0. For example, during a program operation, the results of a program verification phase can be sent to a page buffer (e.g., page buffer 640, which can be the same as page buffer 540). If the cell has been verified to have been programmed, no further programming is required. For example, if the selected memory cells in sub-blocks of the set of sub-blocks 605A have been verified to have the desired logic states, no further programming is required for the selected memory cells. The controller thus turns off the select gate drain transistors SGD0 and SGD1 in the set of sub-blocks 605A. As a result, the sub-blocks 602A₀ and 602A₁in the set 605A become unselected sub-blocks, which are not to be further programmed. The dynamic latch device 606A, which is connected to the unselected sub-blocks 602A₀ and 602A₁, can thus be used as a latch to store program data for programming other selected sub-blocks (not shown in FIG. 6). In FIG. 6, both sets of sub-blocks 605A and 605B can have memory cells that have been programmed and thus have unselected sub-blocks. Therefore, the corresponding dynamic latch devices 606A and 606B can also be referred to as inhibit latches, which can be used to store inhibit data (e.g., program data for programming other sub-blocks) at the respective sense memory nodes SN_0 and SN_1.

With continued reference to FIG. 6, to store program data (or inhibit data), the controller can control the page buffer 640 (or another dynamic latch device) and the dynamic latch device 606A to transfer data to the sense memory node SN_0. For instance, the write transistors 608A₁ and 610A₁can be activated, by the controller, to turn on (e.g., by controlling the gate control signal RE_0 and WE_0) such that the page buffer 640 (or another dynamic latch device) can send data to the sense memory node SN_0 via the global bit line 604. The gate capacitance of the storage device 612A can be configured or sized to hold the electrical charges. In a similar manner, the page buffer 640 can modify the stored data at the sense memory node SN_0. After the data is stored or modified, the transistors 608A₁ and 610A₁can be deactivated (e.g., turn off) to isolate the sense memory node SN_0. The select gate SGD0 and SGD1 in the set of sub-blocks 605A are also deactivated by the controller (e.g., turned off). The storing and modification of data at sense memory node SN_1 can be performed in a similar manner.

With continued reference to FIG. 6, the right side of this figure is used to illustrate how the stored data can be obtained and used to program selected sub-blocks (not shown in FIG. 6). Referring to the dynamic latch device 606B, the program data is stored at the sense memory node SN_1 using the storage device 612B (denoted as STFT_1). The controller can cause the store data at the sense memory node SN_1 to be obtained and transferred to one or more selected sub-blocks or to the page buffer 640 during a programming operation. For instance, during a program operation, transistors 608B₂ and 610B₂ can be activated, by the controller, to turn on (by controlling the gate control signals RE_1 and WE_1) such that the stored data at the sense memory node SN_1 is sent to the page buffer 640 or another dynamic latch device (the data path is shown in the right side of FIG. 6) via the global bit line 604.

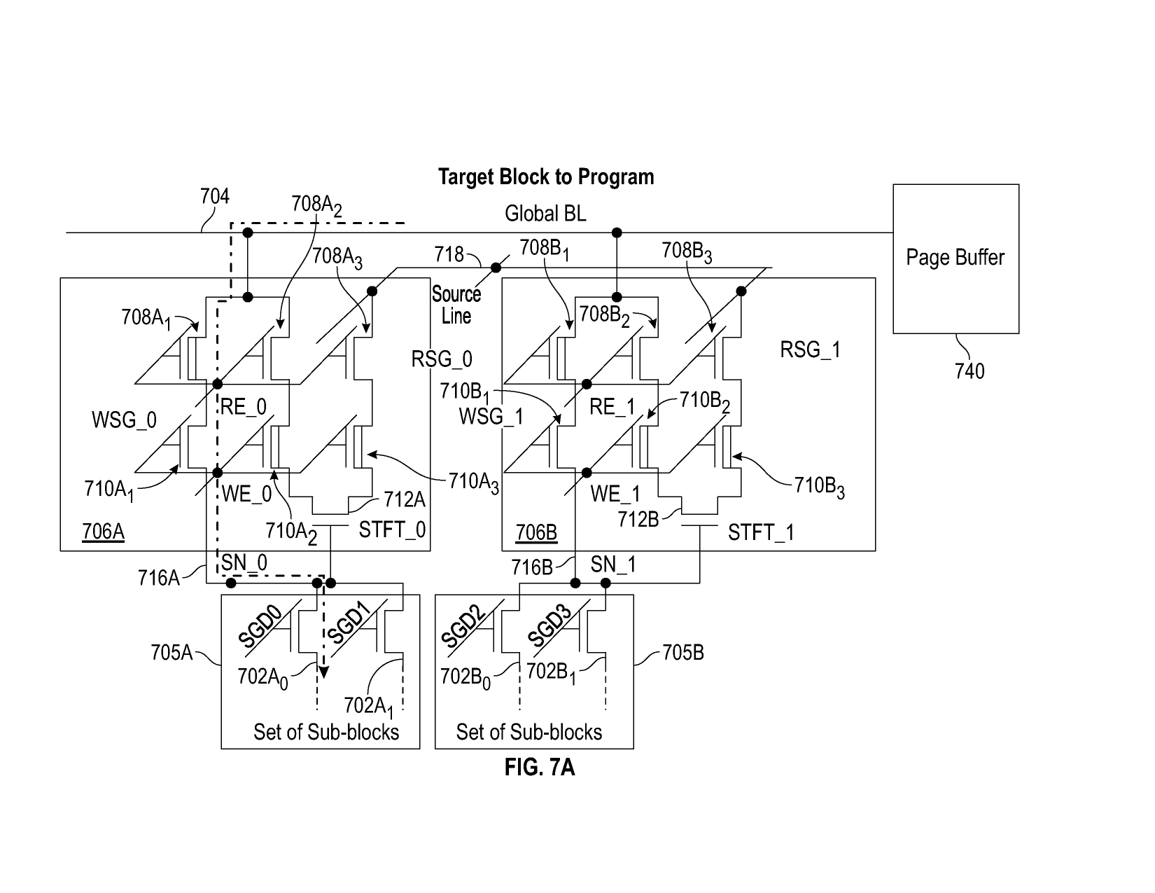

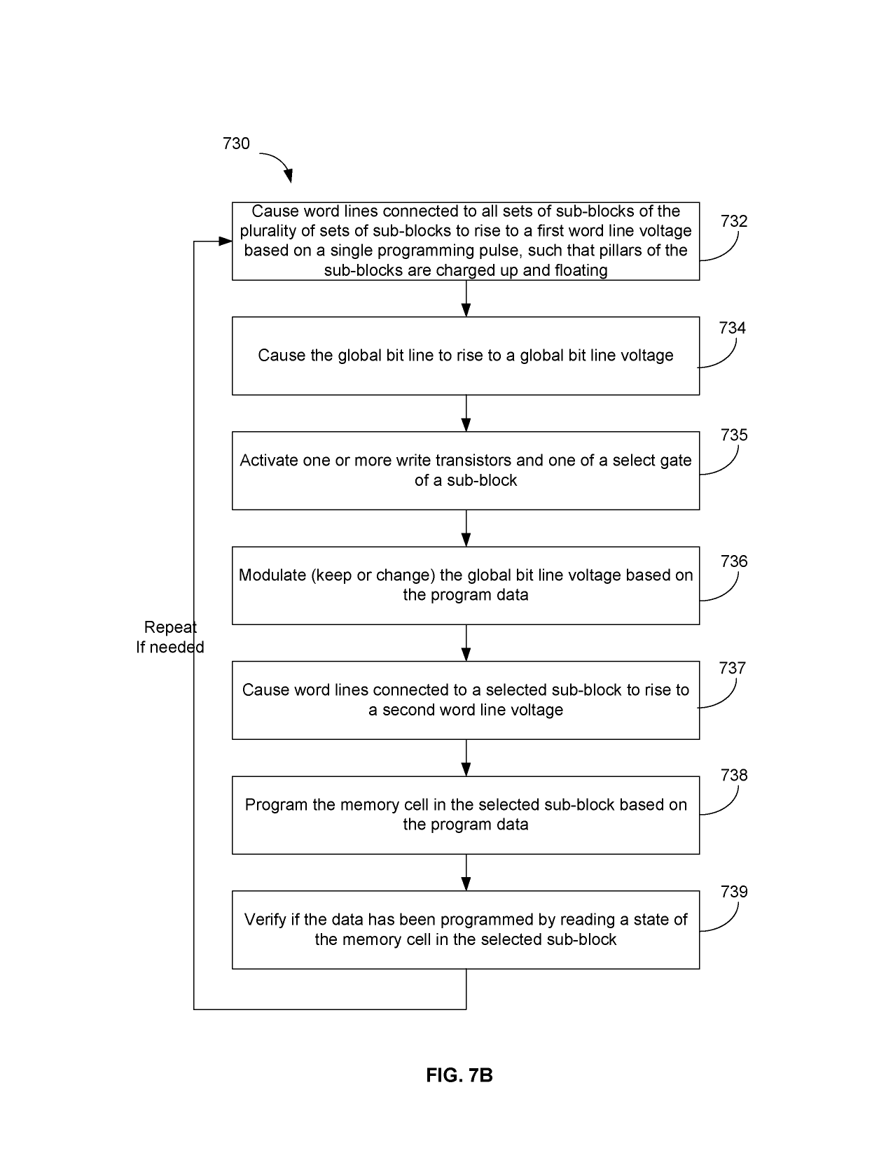

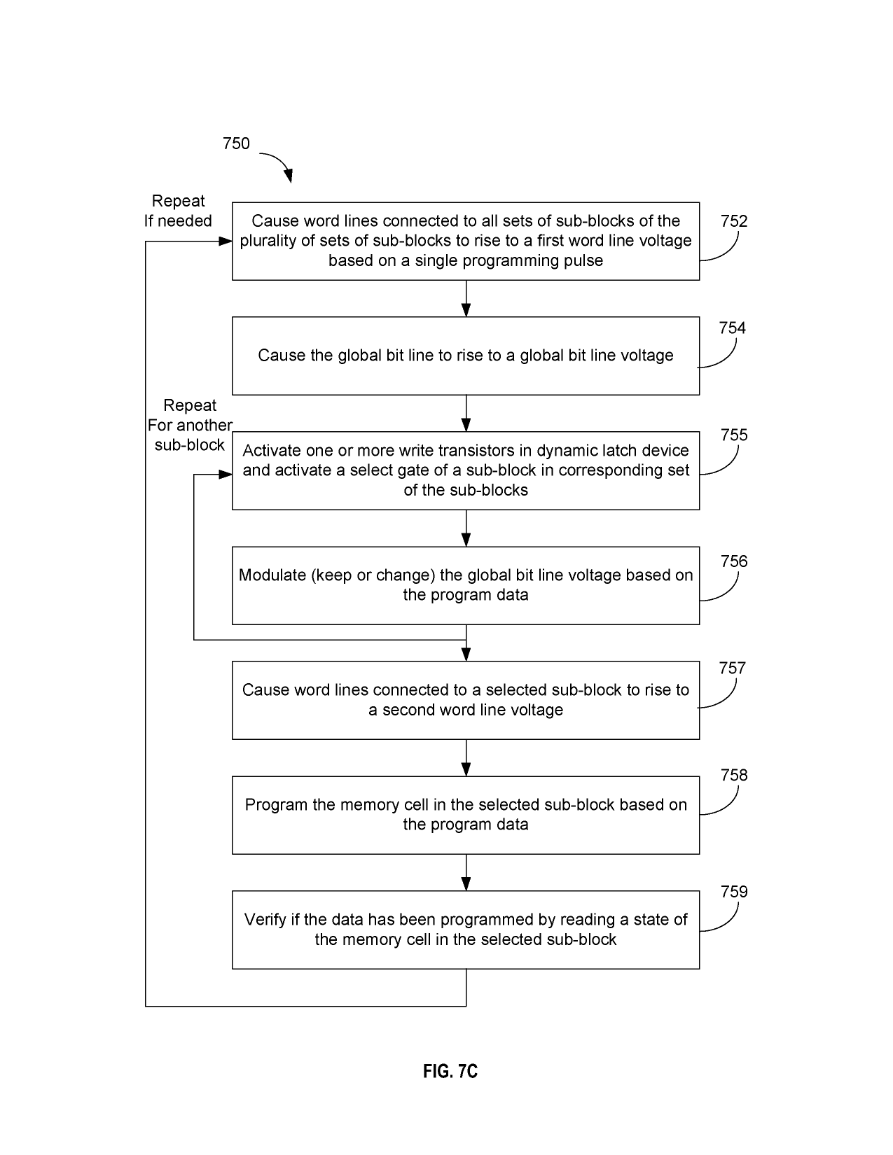

FIG. 6, as described above, illustrates an example dynamic latch device configuration and the use of the dynamic latch device for storing data if the corresponding sub-blocks are unselected sub-blocks (e.g., memory cells in the unselected sub-blocks are already programmed). FIG. 7A illustrates another dynamic latch devices 706A and 706B connected to sets of sub-blocks 705A and 705B, respectively. The circuit configuration of the dynamic latch devices 706A and 706B can be the same as that of dynamic latch devices 606A and 606B, and are thus not repeatedly described. FIG. 7A is used to illustrate using the dynamic latch devices to perform program operation separately (e.g., one sub-block at a time) or parallelly (e.g., multiple sub-blocks at a time).

With reference to FIG. 7A and the flowchart shown in FIG. 7B, in one process 730 of performing a program operation for a memory cell in a selected sub-block, the controller causes (block 732) all word lines connected to all sets of sub-blocks (e.g., all sets of sub-blocks 705) to rise to a first word line voltage (e.g., 10V) based on a single programming pulse. As described above, the word lines are connected to the gate electrodes of the memory cells in the sub-blocks (selected and unselected for programming). Because of the capacitive coupling between the gate electrodes of the memory cells and the pillars of the memory cells in the sub-blocks, the pillars are charged up and floating (if there is no discharge path).

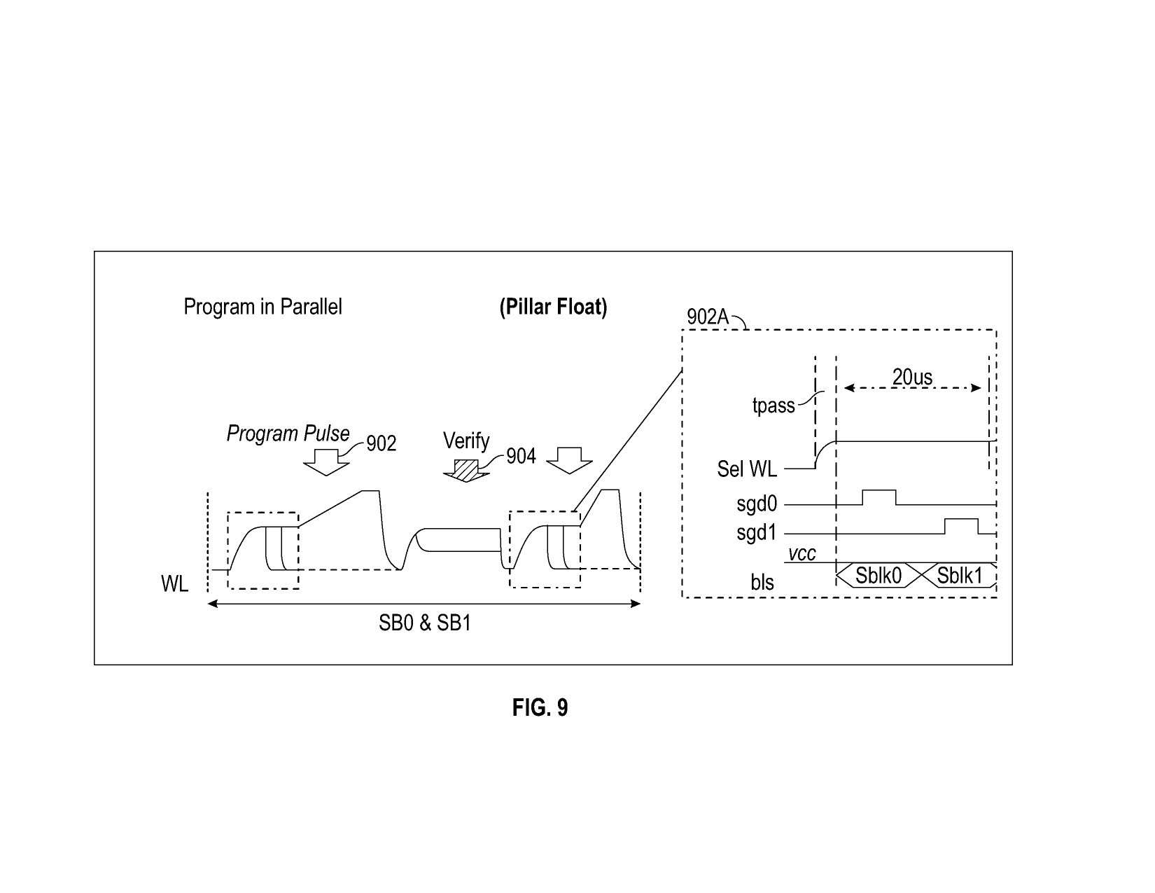

The floating pillar concept is illustrated in more detail using FIGS. 4 and 9. As described below, the floating pillar concept can also enable parallel programming of multiple sub-blocks in a more efficient way. The parallel programming is described in greater detail below using FIGS. 7A and 7C. In FIG. 9, for example, a single programming pulse 902 in a sequence of programming pulses is shown. FIG. 9 shows two programming pulses. The programming operation has a program phase, in which the word line voltage is caused to rise to, e.g., 10V. FIG. 4A illustrates that there is capacitive coupling between the memory cells 208 and pillar 441 (e.g., the gate-channel coupling). Therefore, as the gate electrode of the memory cells 208 receive the voltage applied on the word lines, the capacitive coupling effect charges up the pillar 441. As a result, there is no need for the controller to directly apply a voltage on the pillar 441 (e.g., via the bit lines). This is referred to as the floating pillar effect in this disclosure. The pillar is floating because the select gates (e.g., select line 481 and SGD0 or SGD1 in FIG. 7A) are turned off, thereby isolating the pillar from other circuits.

With reference back to FIGS. 7A, 7B, and 9, in block 734, the controller causes the global bit line 704 to rise to a global bit line voltage (e.g., 3V). In this example, we assume that a memory cell in sub-block 702A₀ is selected to be programed. It is understood that other memory cells in other sub-blocks can be programmed in a similar way. The controller also activates (block 736) one or more write transistors in dynamic latch device 706A and activates one of a select gate of a sub-block. So, for example, if sub-block 702A₀ is to be programmed, the controller activates (e.g., using the control signals RE_0 and/or WE_0) write transistors 708A₁ and 710A₁ (e.g., turn on these write transistors) to receive the program data from the page buffer 740 or from another dynamic latch device storing the program data. The controller also activates the select gate SGD0 of sub-block 702A₀. To activate (e.g., turn on) the write transistors 708A₁ and 710A₁ and the select gate SGD0, the controller can cause a control voltage (e.g., 3V) to be applied to the gate electrodes of these write transistors and the select gate.

Next, the controller causes the voltage level of the global bit line 704 to be modulated (block 736) by, e.g., the page buffer 740, depending on the program data. If the program data is a logic “0”, for example, the controller may cause the global bit line 704 to discharge to 0V. In turn, the pillar of the selected sub-block, which has been pre-charged due to the capacitive coupling effect described above, discharges to 0V because the pillar is connected to the global bit line 704 electrically. If the program data is a logic “1”, for example, the controller may cause the global bit line 704 to remain at the global bit line voltage (e.g., 3V).

In the next block 737, the controller can cause the word lines connected to the memory cells in a selected sub-block to rise to a second word line voltage (e.g., 20V), such that it is a pass voltage to turn on all memory cells that are unselected for programming. In block 738, the controller causes the selected memory cell in the selected sub-block to be programmed according to the program data. In block 739, the controller can cause a program verification operation to be performed to verify the state of the selected memory cell. If it is verified that the selected memory cell has a desired logic state, the program operation is completed, the process 730 can stop. If not, the process 730 can be repeated, e.g., from block 732.

With reference to FIGS. 7A and 7C, a process 750 for performing parallel program operations using dynamic latch devices described herein is described. In block 752, the controller causes all word lines connected to all sets of sub-blocks (e.g., all sets of sub-blocks 705) to rise to a first word line voltage (e.g., 10V) based on a single programming pulse. As described above, the word lines are connected to the gate electrodes of the memory cells in the sub-blocks (selected and unselected for programming). Because of the capacitive coupling between the gate electrodes of the memory cells and the pillars of the memory cells in the sub-blocks, the pillars are charged up and floating (if there is no discharge path).

In block 754, the controller causes the global bit line 704 to rise to a global bit line voltage (e.g., 3V). In this example, we assume that a memory cell in sub-blocks 702A₀ of the set 705A and a memory cell in sub-block 702B₀ of the set 705B are selected to be programed in parallel. That is, for each set of the sub-blocks 705 that connects to a respective dynamic latch device 706, one sub-block is selected for programming a memory cell therein. Thus, in this example, selected memory cells of two selected sub-blocks 702A₀ and 702B₀ in two different sets 705A and 705B are programmed in parallel using a single programming pulse. It is understood that other memory cells in other sub-blocks can be programmed in a similar way in parallel.

In process 750, the blocks 755 and 756 are repeatedly performed for each of the selected sub-blocks. For instance, the controller may first activates (block 755) one or more write transistors in dynamic latch device 706A and activates one of a select gate (e.g., SGD0) of a sub-block (e.g., sub-block 702A₀). So, for example, if sub-block 702A₀ is to be programmed, the controller activates (e.g., using the control signals RE_0 and/or WE_0) write transistors 708A₁ and 710A₁ (e.g., turn on these write transistors) to receive the program data from the page buffer 740 or from another dynamic latch device storing the program data. The controller also activates the select gate SGD0 of sub-block 702A₀. To activate (e.g., turn on) the write transistors 708A₁ and 710A₁ and the select gate SGD0, the controller can cause a control voltage (e.g., 3V) to be applied to the gate electrodes of these write transistors and the select gate.

Next, the controller causes the voltage level of the global bit line 704 to be modulated (block 756) by, e.g., the page buffer 740, depending on the program data. If the program data is a logic “0”, for example, the controller may cause the global bit line 704 to change to 0V. In turn, the pillar of the selected sub-block, which has been pre-charged due to the capacitive coupling effect described above, discharges to 0V. If the program data is a logic “1”, for example, the controller may cause the global bit line 704 to remain at the global bit line voltage (e.g., 3V).

The blocks 755 and 756 are then repeated for the next selected sub-block (e.g., sub-block 702B₀). In this case, the controller uses a different dynamic latch device 706B. The controller activates (block 755) one or more write transistors in dynamic latch device 706B and activates one of a select gate (e.g., SGD2) of a sub-block. So, for example, if sub-block 702B₀ is to be programmed, the controller activates (e.g., using the control signals RE_1 and/or WE_1) write transistors 708B₁ and 710B₁ (e.g., turn on these write transistors) to receive the program data from the page buffer 740 or from another dynamic latch device storing the program data. The program data for programming sub-block 702B₀ may be the same or different from the program data for programming sub-block 702A₀. The controller also activates the select gate SGD2 of sub-block 702B₀. To activate (e.g., turn on) the write transistors 708B₁ and 710B₁ and the select gate SGD2, the controller can cause a control voltage (e.g., 3V) to be applied to the gate electrodes of these write transistors and the select gate.

Next, the controller causes the voltage level of the global bit line 704 to be modulated (block 756) by, e.g., the page buffer 740, depending on the program data for programming sub-block 702B₀. If the program data is a logic “0”, for example, the controller may cause the global bit line 704 to change to 0 V. In turn, the pillar of the selected sub-block, which has been pre-charged due to the capacitive coupling effect described above, discharges to 0 V. If the program data is a logic “1”, for example, the controller may cause the global bit line 704 to remain at the global bit line voltage (e.g., 3V).

The above two blocks 755 and 756 in process 750 can be repeated as many times as desired, depending on the number of sub-blocks selected for programming. Because each sub-block selected is in a different set of sub-blocks 705, the program data for different selected sub-blocks can be delivered to different sub-blocks 705 without interfering with one another. This is enabled by the circuit configuration where different dynamic latch devices 706 are connected to respectively different sets of sub-blocks 705, and no other set of sub-blocks, as illustrated in FIG. 7A.

In the next block 757 of process 750 shown in FIG. 7C, the controller can cause the word lines connected to the memory cells in the multiple selected sub-blocks to rise to a second word line voltage (e.g., 20V), such that it is a pass voltage to turn on all memory cells that are not selected for programming. In block 758, the controller causes the selected memory cells in the multiple selected sub-blocks to be programmed in parallel (e.g., simultaneously) according to their respective program data. Therefore, using the circuit configuration of the dynamic latch devices shown in FIG. 7A, the program operation can be performed to multiple sub-blocks in parallel, thereby improving the operational efficiency. In this example, the multiple sub-blocks are from different sets of sub-blocks, and cannot be in the same set of sub-blocks (unless more than one dynamic latch device is used for each set of the sub-blocks). Furthermore, the program operations are performed using a single programming pulse. In other words, the controller only applies one programming pulse to the word lines for programming all selected sub-blocks in parallel. Ramping up the word line voltages may take a significant amount of time. As a result, by programming multiple sub-blocks in parallel, the latency of programming multiple memory cells in selected sub-blocks can greatly reduced. In block 759, the controller can cause a program verification operation to be performed to verify the state of the multiple memory cells. If the verification is successful, the program is completed, and the process 750 can stop. If not, the process 750 can be repeated, e.g., from block 752.

The above description of the parallel program operation uses two sub-blocks (e.g., sub-blocks 702A₀ and 702B₀) as an example. In other embodiments, more sub-blocks can be programmed in parallel using the process 750 and the circuit configuration described herein. For instance, if a memory plane has two memory blocks and each block has four sets of sub-blocks, the controller can be configured to program in parallel, using the plurality of dynamic latch devices connected to the different sets of sub-blocks, at least four sub-blocks in one memory block and at least four other sub-blocks in another memory block. It is understood that the number of sub-blocks that can be programmed in parallel may change depending on the number of dynamic latch devise, the number of sets of sub-blocks in a memory block, and the number of memory blocks in a memory plane. For instance, in one example, each of the plurality of dynamic latch devices may be connected to between one and four sub-blocks. The plurality of dynamic latch devices comprises at least 5-80 dynamic latch devices (e.g., 20) per global bit line per plane. The parallel program capabilities can be thus scaled by scaling up the number of the dynamic latch devices.

In a parallel program operation, the controller can be configured to perform operations to cause at least two selected sub-blocks to be programed in parallel using program data obtained from the page buffer and/or from other dynamic latch devices storing program data. In some examples, the program data can come from a combination of page buffers and dynamic latch devices connected to unselected sub-blocks (e.g., inhibited latches).

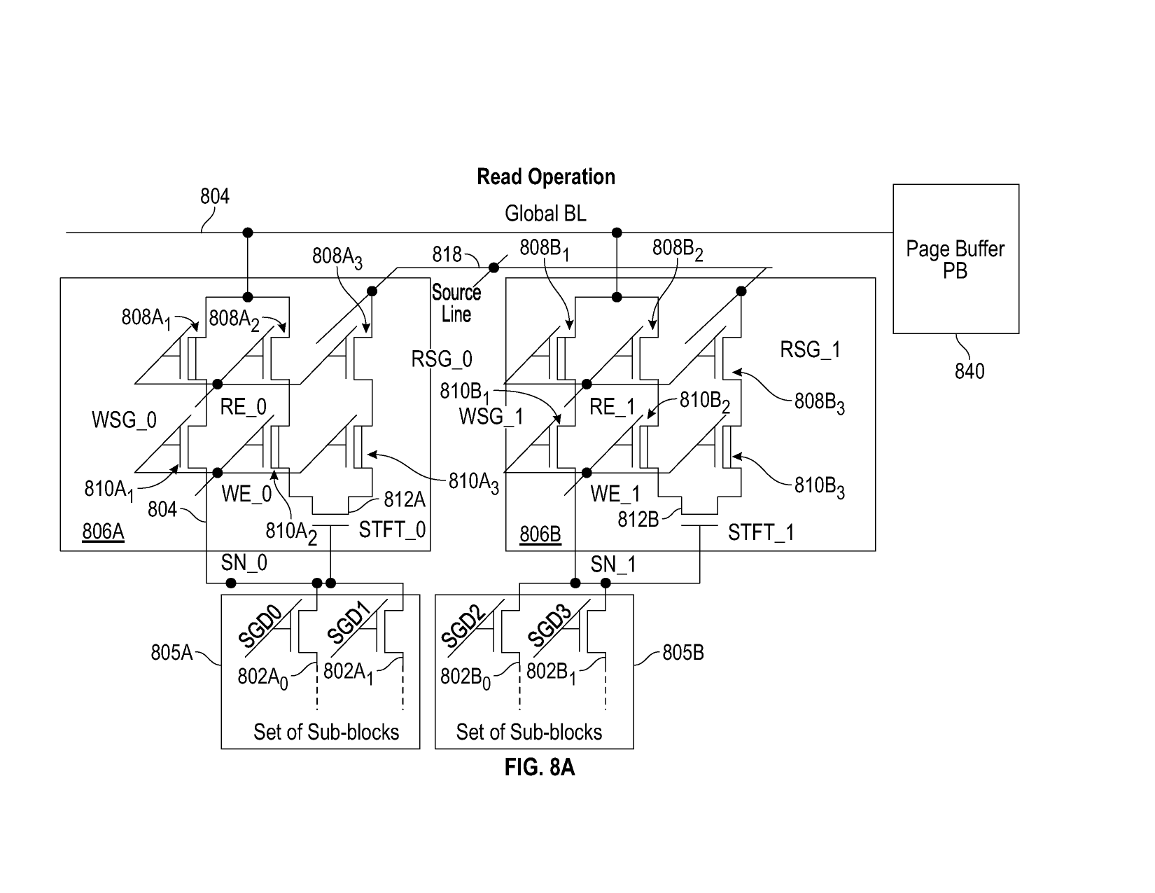

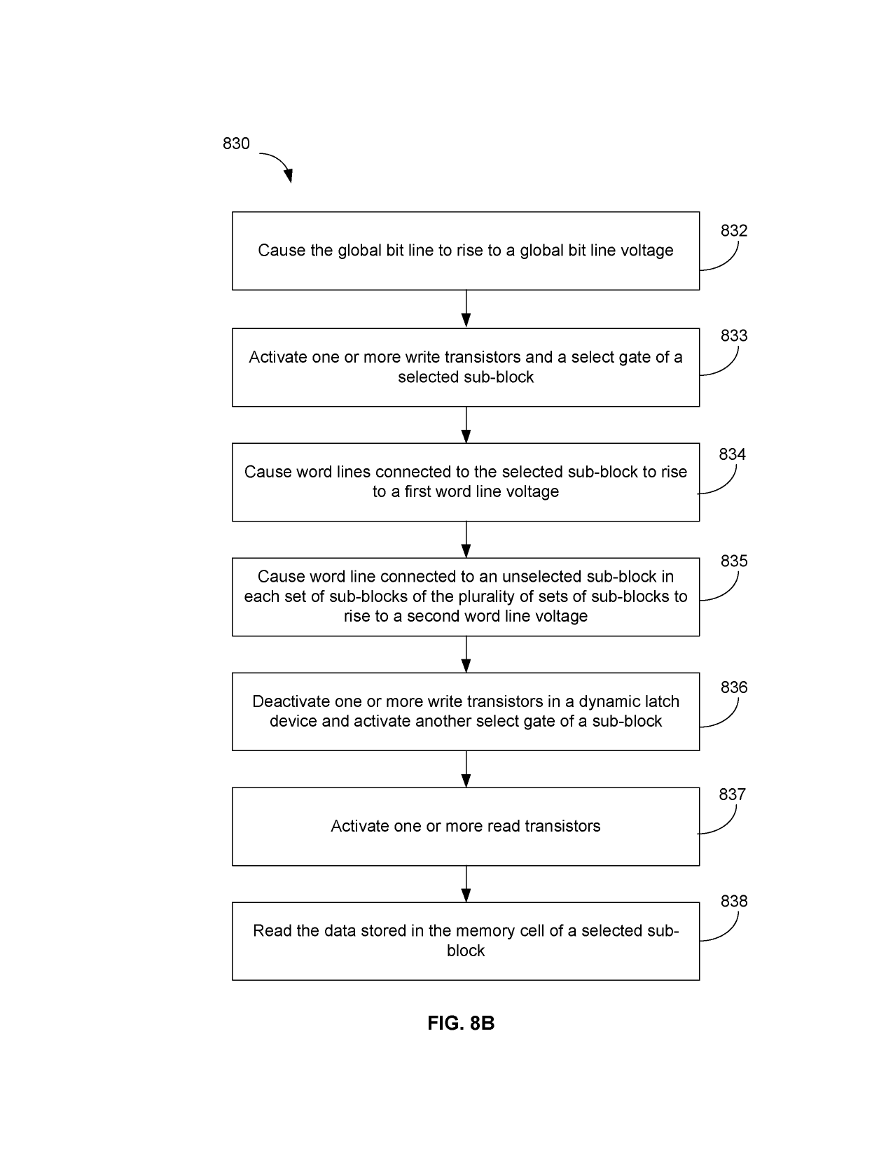

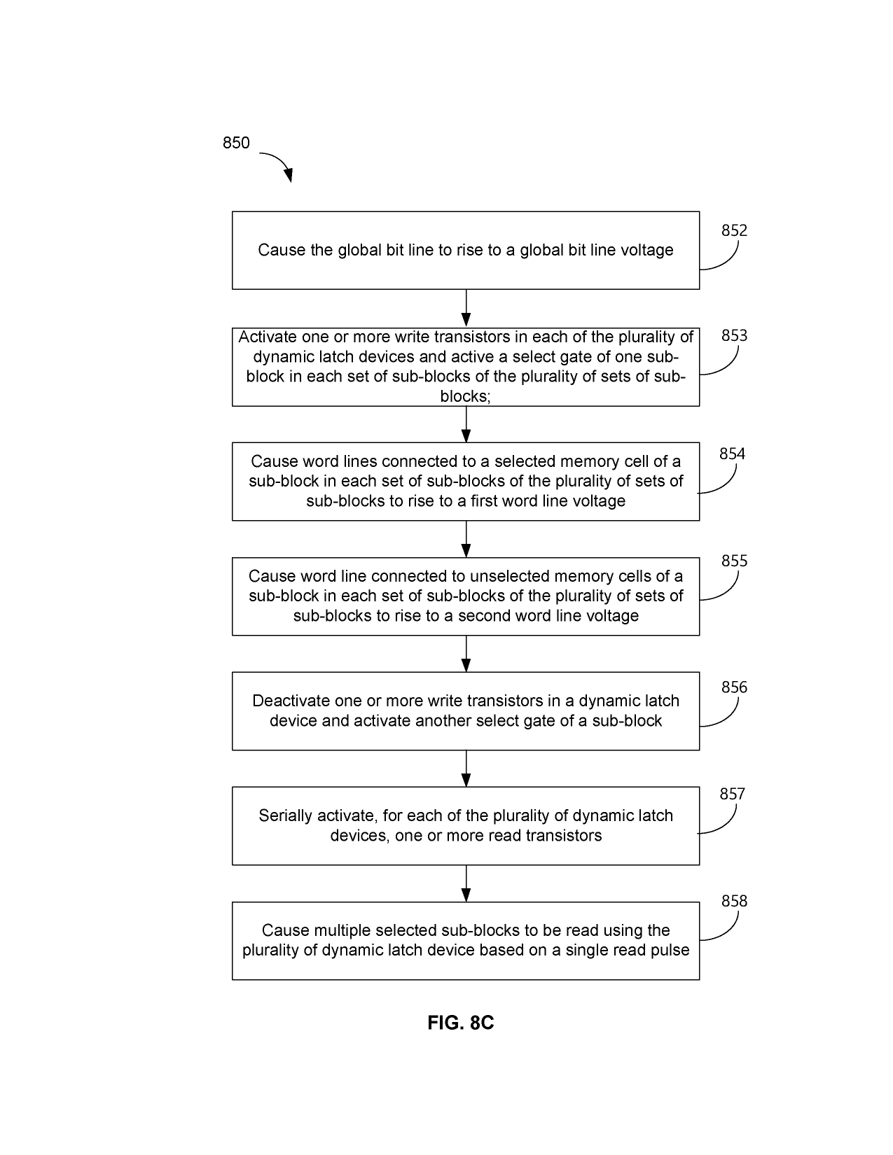

FIG. 8A-8C illustrates using the dynamic latch device configuration described herein to perform read operation or program verify operation. The circuit configuration shown in FIG. 8A is the same or similar to those shown in FIG. 6 and 7A, and are thus not repeatedly described. In performing read or program verify operations, the sense memory node (e.g., SN_0 or SN_1) in a dynamic latch device connected to a selected sub-block for reading is not used to store data. During read operations, the dynamic latch device (e.g., 806A or 806B) can be configured to perform sense amplification for improving the sensing capability of the page buffer.

With reference to FIGS. 8A and 8B, in block 832, the controller causes the global bit line to rise to a global bit line voltage (e.g., 3V). In block 833, the controller activates one or more write transistors (e.g., 808A₁ and 810A₁) and activates a select gate (e.g., SGD0) of a selected sub-block (e.g., sub-block 802A₀) from which a memory cell is being read. As a result, the pillar (or channel) of the memory cells in the selected sub-block is also raised to the global bit line voltage (e.g., 3V) because the pillar is electrically connected to the global bit line 804.

In block 834, the controller causes word lines connected to a selected memory cell in a selected sub-block (e.g., sub-block 802A₀) to rise to a first word line voltage (e.g., 2V). In block 835, the controller causes word lines connected to unselected memory cells in the selected sub-block (e.g., sub-block 802A₀) to rise to a second word line voltage (e.g., 6V). The second word line voltage may be higher than the first word line voltage such that the unselected memory cells turn on for enabling the read operation of the selected memory cell.

In block 836, the controller causes the one or more write transistors (e.g., 808A₁ and 810A₁) in the dynamic latch device (e.g., device 806A) to deactivate, thereby isolating the global big line from the set of sub-blocks (e.g., set 805A) connected to the dynamic latch device. In some examples, the controller further activates another select gate (e.g., the SGS shown in FIG. 2A, not shown in FIG. 8B) of the selected sub-block. The another selected gate may be the select gate source (SGS) located at the opposite end of the string of memory cells from the selected gate drain (SGD, both shown in FIG. 2A). When the select gate source is activated, the string of memory cells in the selected sub-block is connected to the source line SRC (e.g., source line 818). Therefore, if the threshold voltage of the memory cell to-be-read in the selected sub-block is greater than the applied word line voltage (e.g., if Vt > 2V), the sense memory node of the dynamic latch device (e.g., the SN_0 node) remains the same. Otherwise, the sense memory node is discharged through the source line.

Next, the controller can activate (block 837) one or more read transistors. Continuing with the above example, the controller can use the control signals RE_0 and WE_0 to activate (e.g., turn on) the transistors 808A₃ and 810A₃. The controller may also activate transistors 808A₂ and 810A₂. If the sense memory node remains the same (i.e., the threshold voltage of the memory cell to-be-read is greater than the applied word line voltage), the storage device 812A is activated because the gate-source voltage of device 812A is greater than its threshold voltage. Because the combination of read transistors 808A₃ and 810A₃ is connected to the source line 818, the global bit line 804 is pulled down. If the sense memory node SN_0 is discharged (i.e., the threshold voltage of the memory cell to-be-read in the selected sub-block is no greater than the applied word line voltage), the storage device 812A is not activated (e.g., remain turned off). In turn, the global bit line 804 is not pull down and remains the same. In this way, the data stored in the memory cell in the selected sub-block (e.g., sub-block 802A₀) can be read (block 838) or transferred to the page buffer 840.

During the read operation, the storage device in a dynamic latch device thus functions as switch and the read transistors (and/or other transistors) can be scaled to perform sense amplification during a read operation. As described above, nowadays, the 3D memory device has more and more memory cells in a string of memory cells of a sub-block. The memory cells in the same string share a same pillar (or channel region). Therefore, the pillar current becomes smaller and smaller as the number of the memory cells increases. The pillar current may be, for example, in the pico amp range. This small pillar current makes it difficult and time consuming for the page buffer to perform sensing during a read operation. In particular, the pillar of the string of memory cells in a sub-block is connected to the global bit line, which in turn is connected to the page buffer. Thus, conventionally, the sense amplifier in the page buffer directly senses the pillar current. Because the pillar current is so small, the sensing can be challenging and time consuming.

In the present disclosure, the global bit line is no longer directly connected to the pillar of the string of memory cells in a sub-block. A dynamic latch device is disposed between the global bit line and the strings of memory cells in a sub-block, as shown in FIG. 8A. As described above, during the read operation, the storage device 812A functions as a switch controlled by the sense memory node SN_0, which remains at the same voltage or discharged depending on the threshold voltage of the memory cell being read. Therefore, the storage device 812A is activated or not activated depending on the state of the memory cell being read (via the pillar current). The read transistors (and other transistors) in the dynamic latch device (e.g., 808A₂, 808A₃, 810A₂, and/or 810A₃of device 806A) can be scaled (e.g., having a bigger device area) to supply a larger enough current to the sense amplifier in the page buffer (e.g., page buffer 840), such that the sense amplification can be performed more effectively with higher accuracy and lower latency. In other words, the sense amplifier in the page buffer 840 no longer senses the pillar current directly. The pillar current in any sub-block is only used to switch the transistor 812A. As such, the dynamic latch device disclosed herein also improves the read operation performance.

The dynamic latch devices disclosed herein can further enable parallel read operations in which multiple memory cells are read in parallel. FIG. 8C illustrates a flowchart of an example process 850 for performing read operations in parallel to read multiple memory cells. For illustration purposes, the below description uses two memory cells in two selected sub-blocks 802A₀ and 802B₀ as an example. It is understood that more memory cells in different selected sub-blocks can be read in a similar manner. With reference to FIGS. 8A and 8C, in block 852, the controller causes the global bit line to rise to a global bit line voltage (e.g., 3V). In block 853, the controller activates one or more write transistors in each of the plurality of dynamic latch devices and activates a select gate of one sub-block in each set of sub-blocks of the plurality of sets of sub-blocks. For example, in FIG. 8A, the controller can control the signals RE_0, WE_0, RE_1, and/or WE_1 to activate transistors 808A₁ and 810A₁ in device 806A and transistors 808B₁ and 810B₁ in device 806B. Thus, two dynamic latch devices 806A and 806B are operated in parallel to connect the global bit line 804 to their respective selected sub-blocks for reading. As a result, the pillars (or channel) of the memory cells in the two selected sub-blocks (e.g., sub-block 802A₀ and 802B₀) are also raised to the global bit line voltage (e.g., 3V).

In block 854, the controller causes word lines connected to a selected memory cell in each of the selected sub-blocks (e.g., sub-block 802A₀ and 802A₁) to rise to a first word line voltage (e.g., 2V). In block 855, the controller causes word lines connected to the unselected memory cells in the same selected sub-blocks (e.g., sub-block 802A₀ and 802A₁) to rise to a second word line voltage (e.g., 6V). The second word line voltage may be higher than the first word line voltage such that the unselected memory cells are turned on.

In block 856, the controller causes the one or more write transistors in each of the multiple dynamic latch devices to deactivate, thereby isolating the global bit line from the multiple sets of sub-blocks connected to the dynamic latch devices. Referring to FIG. 8A, for instance, the controller controls the RE_0, WE_0, RE_1, and/or WE_1 control signals to deactivate the write transistors 808A₁, 810A₁, 808B₁, and 810B₁, thereby isolating the global bit line 804 from the sets of sub-blocks 805A and 805B. In some examples, the controller further activates another select gate (e.g., the SGS shown in FIG. 2A, not shown in FIG. 8A) of the selected sub-blocks. The another selected gate may be the select gate source (SGS) located at the opposite end of the string of memory cells from the selected gate drain (SGD, shown in FIG. 2A). After the select gate source is activated, the string of memory cells in each of the selected sub-block (e.g., 802A₀ and 802B₀) is connected to the source line SRC (e.g., source line 818). Therefore, if the threshold voltage of a memory cell being read in a selected sub-block is greater than the applied word line voltage (e.g., if Vt > 2V), the sense memory node of the respective dynamic latch device remains the same. Otherwise, the sense memory node is discharged through the source line. So referring to FIG. 8A, for instance, for a selected memory cell in sub-block 802A₀, if the threshold voltage Vt of the selected memory cell is greater than the word line voltage, the sense memory node SN_0 stays at the same voltage; otherwise, it is discharged to the ground voltage (e.g., 0 V). Similarly, for a selected memory cell in sub-block 802B₀, if the threshold voltage Vt of the selected memory cell is greater than the word line voltage, the sense memory node SN_1 stays at the same voltage; otherwise, it is discharged to ground voltage (e.g., 0 V). Therefore, the voltages of sense memory nodes SN_0 and SN_1 in different dynamic latch devices 806A and 806B represent the logic states of the selected memory cells in different sub-blocks of different sets of sub-blocks 805A and 805B respectively. In this manner, the data stored in multiple memory cells in different sub-blocks of different sets are transferred to the sense memory nodes in different dynamic latch devices in parallel.

Next, the controller can serially activate (block 857) one or more read transistors in each of the plurality of dynamic latch devices. Continuing with the above example, the controller activates read transistors in dynamic latch device 806A, followed by activating read transistors in dynamic latch device 806B. Specifically, the controller can use the control signals RE_0 and WE_0 to activate (e.g., turn on) the read transistors 808A₃ and 810A₃, and transistors 808A₂ and 810A₂ in device 806A. If the sense memory node SN_0 remains the same (i.e., the threshold voltage of the memory cell being read is greater than the applied word line voltage), then the storage device 812A is activated because the gate-source voltage of device 812A is greater than its threshold voltage. Because transistors 808A₃ and 810A₃ are connected to source line 818, the global bit line 804 is pulled down. If the sense memory node SN_0 is discharged (i.e., the threshold voltage of the memory cell being read in the selected sub-block is no greater than the applied word line voltage), the storage device 812A is not activated (e.g., remain turned off). In turn, the global bit line 804 is not pulled down and remains the same. In this way, the data stored in the selected memory cell in the sub-block 802A₀) is read (block 858) into the page buffer 840.

Next, the controller can use the control signals RE_1 and WE_1 to activate (e.g., turn on) the read transistors 808B₃ and 810B₃, and transistors 808B₂ and 810B₂ in dynamic latch device 806B. If the sense memory node SN_1 remains the same (i.e., the threshold voltage of the memory cell being read is greater than the applied word line voltage), then the storage device 812B is activated because the gate-source voltage of device 812B is greater than its threshold voltage. Because transistors 808B₃ and 810B₃ are connected to source line 818, the global bit line 804 is pulled down. If the sense memory node SN_1 is discharged (i.e., the threshold voltage of the memory cell being read in the selected sub-block is no greater than the applied word line voltage), the storage device 812B is not activated (e.g., remains turned off). In turn, the global bit line 804 is not pulled down and remains the same. In this way, the data stored in the selected memory cell in the sub-block 802B₀) is read (block 858) into the page buffer 840.

Accordingly, in the parallel read operation, data stored in different memory cells in different sub-blocks can be read to, or transferred to, the respective sense memory nodes (e.g., SN_0 and SN_1) in parallel, and then serially sensed by the sense amplifier in the page buffer. This way, the read operation efficiency is also improved.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the embodiments. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended embodiments. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the embodiments, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A three-dimensional memory device comprising:
an array of memory cells comprising a plurality of memory blocks having a first memory block, the first memory block including a plurality of sets of sub-blocks;
a global bit line;
a controller; and
a plurality of dynamic latch devices connected between the global bit line and the plurality of sets of sub-blocks, wherein:
a first dynamic latch device of the plurality of dynamic latch devices is connected to a first set of sub-blocks of the plurality of sets of sub-blocks,
different dynamic latch devices of the plurality of dynamic latch devices are connected to different sets of sub-blocks of the plurality of sets of sub-blocks, and
the first dynamic latch device is controllable by the controller to store program data during a program operation in which the first set of sub-blocks connected to the first dynamic latch device are unselected sub-blocks during the program operation.

2. The three-dimensional memory device of claim 1, further comprising a page buffer, wherein during the program operation, the controller is configured to:
obtain the program data from the first dynamic latch device instead of from the page buffer; and
perform the program operation of one or more sub-blocks that are not connected to the first dynamic latch device, the one or more sub-blocks are selected sub-blocks in the plurality of sets of sub-blocks for performing the program operation.

3. The three-dimensional memory device of claim 1, wherein each of the plurality of dynamic latch devices comprises:
a storage device;
a plurality of write transistors connected between the global bit line and the storage device; and
a plurality of read transistors connected between the storge device and a source line; wherein:
the storage device is connected between the plurality of write transistors and the plurality of read transistors, the storage device being controllable to store data at a sense memory node.

4. The three-dimensional memory device of claim 1, wherein the controller is further configured to:
cause word lines connected to all sets of sub-blocks of the plurality of sets of sub-blocks to rise to a first word line voltage based on a single programming pulse, such that pillars of memory cells in the plurality sets of sub-blocks are charged up and floating;
cause the global bit line to rise to a global bit line voltage;
perform, for each sub-block in the plurality set of the plurality of sets sub-blocks:
activate one or more write transistors in a dynamic latch device of the plurality of dynamic latch devices and activate a select gate of a sub-block in a corresponding set of sub-blocks of the plurality of sets of sub-blocks;
modulate the global bit line voltage to remain the same or change based on the program data;
cause word lines connected to a selected sub-block in each set of sub-blocks of the plurality of sets of sub-blocks to rise to a second word line voltage; and
program multiple selected sub-blocks via the plurality of dynamic latches based on a single programming pulse.

5. The three-dimensional memory device of claim 1, wherein the controller is configured to program in parallel, using the plurality of dynamic latch devices, at least four sub-blocks of the first memory block and at least four other sub-blocks in another memory block.

6. The three-dimensional memory device of claim 1, wherein a dynamic latch device of the plurality of latch devices comprises a plurality of read transistors configured to perform sense amplification during a read operation.

7. The three-dimensional memory device of claim 1, wherein the controller is further configured to:
cause the global bit line to rise to a global bit line voltage;
activate one or more write transistors in each of the plurality of dynamic latch devices and active a select gate of one sub-block in each set of sub-blocks of the plurality of sets of sub-blocks;
cause word lines connected to a selected memory cell of a sub-block in each set of sub-blocks of the plurality of sets of sub-blocks to rise to a first word line voltage;
cause word lines connected to unselected memory cells of the sub-block in each set of sub-blocks of the plurality of sets of sub-blocks to rise to a second word line voltage;
deactivate one or more write transistors in each of the plurality of dynamic latch devices and activate another select gate of one sub-block in each set of sub-blocks of the plurality of sets of sub-blocks; and
serially activate, for each of the plurality of dynamic latch devices, one or more read transistors, and cause multiple selected sub-blocks to be read using the plurality of dynamic latch device based on a single read pulse.

8. The three-dimensional memory device of claim 1, wherein the first set of sub-blocks comprises at least two sub-blocks, the at least two sub-blocks being connected to the first dynamic latch device and no other dynamic latch devices.

9. The three-dimensional memory device of claim 1, wherein the plurality of dynamic latch devices are physically disposed above the array of memory cells, wherein other latch devices in a page buffer are physically disposed below the array of memory cells.

10. The three-dimensional memory device of claim 1, wherein the plurality of dynamic latch devices comprises at least 20 dynamic latch devices per global bit line per plane.

11. The three-dimensional memory device of claim 1, further comprising a page buffer connected to the global bit line, wherein the controller is further configured to perform operations to cause at least two selected sub-blocks of the plurality of sets of sub-blocks to be programed in parallel using program data obtained from the page buffer.

12. The three-dimensional memory device of claim 1, wherein the controller is configured to cause the program data to be stored at a sense memory node in the first dynamic latch device.

13. The three-dimensional memory device of claim 12, wherein the first dynamic latch device comprises a storage device comprising a switch transistor having a gate terminal connected to the sense memory node.

14. The three-dimensional memory device of claim 1, wherein each of the plurality of dynamic latch devices is connected to between one and four sub-blocks.

15. The three-dimensional memory device of claim 1, wherein the array of memory cells comprises tri-level or quad-level memory cells.

16. A method performed by a three-dimensional memory device comprising a plurality of memory blocks having a first memory block, the first memory block including a plurality of sets of sub-blocks, the method comprising:
causing a global bit line to rise to a global bit line voltage;
activating one or more write transistors in each of a plurality of dynamic latch devices and activating a select gate of one sub-block in each set of sub-blocks of the plurality of sets of sub-blocks;
causing word lines connected to a selected memory cell of a sub-block in each set of sub-blocks of the plurality of sets of sub-blocks to rise to a first word line voltage;
causing word lines connected to unselected memory cells of the sub-block in each set of sub-blocks of the plurality of sets of sub-blocks to rise to a second word line voltage;
deactivating one or more write transistors in each of the plurality of dynamic latch devices and activating another select gate of one sub-block in each set of sub-blocks of the plurality of sets of sub-blocks; and
serially activating, for each of the plurality of dynamic latch devices, one or more read transistors, and causing multiple selected sub-blocks to be read using the plurality of dynamic latch device based on a single read pulse.

17. A method performed by a three-dimensional memory device comprising a plurality of memory blocks having a first memory block, the first memory block including a plurality of sets of sub-blocks, the method comprising:
causing word lines connected to all sets of sub-blocks of the plurality of sets of sub-blocks to rise to a first word line voltage based on a single programming pulse, such that pillars of memory cells in the plurality sets of sub-blocks are charged up and floating;
causing the global bit line to rise to a global bit line voltage;
performing, for each sub-block in the plurality set of the plurality of sets sub-blocks:
activating one or more write transistors in a dynamic latch device of a plurality of dynamic latch devices and activating a select gate of a sub-block in a corresponding set of sub-blocks of the plurality of sets of sub-blocks;
modulating the global bit line voltage to remain the same or change based on program data;
causing word lines connected to a selected sub-block in each set of sub-blocks of the plurality of sets of sub-blocks to rise to a second word line voltage; and
programing multiple selected sub-blocks via the plurality of dynamic latches based on a single programming pulse.

18. A memory system comprising:
a processor; and
a memory device coupled to the processor, the memory device comprising:
an array of memory cells comprising a plurality of memory blocks having a first memory block, the first memory block including a plurality of sets of sub-blocks;
a global bit line;
a controller; and
a plurality of dynamic latch devices connected between the global bit line and the plurality of sets of sub-blocks, wherein:
a first dynamic latch device of the plurality of dynamic latch devices is connected to a first set of sub-blocks of the plurality of sets of sub-blocks,
different dynamic latch devices of the plurality of dynamic latch devices are connected to different sets of sub-blocks of the plurality of sets of sub-blocks, and
the first dynamic latch device is controllable by the controller to store program data during a program operation in which the first set of sub-blocks connected to the first dynamic latch device are unselected sub-blocks during the program operation.
